(19) United States
(12) Patent Application Publication
(10) Pub. No.: US 2012/0106252 A1
(43) Pub. Date: May 3, 2012

(54) NONVOLATILE SEMICONDUCTOR MEMORY DEVICE AND METHOD OF MANUFACTURING SAME

(75) Inventors: Tohru OZAKI, Shinagawa-ku (JP); Mitsuhiro NOGUCHI, Yokohama-shi (JP)

(73) Assignee: KABUSHIKI KAISHA TOSHIBA, Tokyo (JP)

(21) Appl. No.: 13/283,034

(22) Filed: Oct. 27, 2011

(30) Foreign Application Priority Data
Nov. 2, 2010 (JP) P2010-245868

(51) Int. Cl. G11C 16/04; H01L 21/311

(52) U.S. Cl. 365/185.05; 438/703; 257/E21.249

(57) ABSTRACT

A nonvolatile semiconductor memory device includes a first region, a second region, and a plurality of word lines. The first region includes a plurality of electrically-rewritable memory transistors. The second region is located around the first region. The plurality of word lines are connected to the gates of the plurality of memory transistors respectively. The plurality of word lines includes interconnection portions and connection portions respectively. The interconnection portions extend in a first direction to head from the first region to the second region and are arrayed in a second direction orthogonal to the first direction with a first distance therebetween. The connection portions are extending from the interconnection portions, located in the second region, and electrically connected to contacts, respectively. The ends of the plurality of connection portions are formed along straight lines extending in the second direction.

### CROSS REFERENCE TO RELATED APPLICATIONS

This application is based on and claims the benefit of priority from prior Japanese Patent Application No. 2010-245868, filed on Nov. 2, 2010, the entire contents of which are incorporated herein by reference.

### FIELD

Embodiments described herein relate generally to an electrically data-rewritable nonvolatile semiconductor memory device and a method of manufacturing the same.

### BACKGROUND

In recent years, side-wall processes is used along with the increasing trend for miniaturization and memory capacity expansion of NAND type flash memories. In a side-wall process, a mask layer is first formed on a material to be etched. Then, a side wall film is formed on the side walls of the mask layer. Then, after the mask layer is removed, the material to be etched is processed with the side wall film used as a mask. Such a side-wall process enables the material to be processed to half the critical dimension obtained by the stepper. However, a further miniaturization is required of interconnection lines to be connected to memory cells.

### BRIEF DESCRIPTION OF THE DRAWINGS

FIG. 1 is a circuit diagram of a nonvolatile semiconductor memory device according to a first embodiment.

FIG. 2 is a top view showing word lines WL according to the first embodiment in a peripheral region AR2.

FIG. 3A is a top view showing a manufacturing step of the nonvolatile semiconductor memory device according to the first embodiment.

FIG. 3B is a cross-sectional view of a part of FIG. 3A.

FIG. 3C is a top view showing a manufacturing step of the nonvolatile semiconductor memory device according to the first embodiment.

FIG. 3D is a cross-sectional view of FIG. 3C taken along a line A-A′.

FIG. 3E is a top view showing a manufacturing step of the nonvolatile semiconductor memory device according to the first embodiment.

FIG. 3F is a cross-sectional view of FIG. 3E taken along a line A-A′.

FIG. 3G is a top view showing a manufacturing step of the nonvolatile semiconductor memory device according to the first embodiment.

FIG. 3H is a cross-sectional view of FIG. 3G taken along a line A-A′.

FIG. 3I is a top view showing a manufacturing step of the nonvolatile semiconductor memory device according to the first embodiment.

FIG. 3J is a cross-sectional view of FIG. 3I taken along a line A-A′.

FIG. 3K is a top view showing a manufacturing step of the nonvolatile semiconductor memory device according to the first embodiment.

FIG. 3L is a cross-sectional view of FIG. 3K taken along a line A-A′.

FIG. 3M is a top view showing a manufacturing step of the nonvolatile semiconductor memory device according to the first embodiment.

FIG. 3N is a cross-sectional view of FIG. 3M taken along a line A-A′.

FIG. 3O is a top view showing a manufacturing step of the nonvolatile semiconductor memory device according to the first embodiment.

FIG. 4 is a top view showing word lines WL according to a second embodiment in a peripheral region AR2.

FIG. 5 is a top view showing word lines WL according to a third embodiment in a peripheral region AR2.

FIG. 6A is a top view showing word lines WL according to a fourth embodiment in a peripheral region AR2.

FIG. 6B is a top view showing word lines WL according to the fourth embodiment in a peripheral region AR2.

FIG. 7A is a top view showing a manufacturing step of a nonvolatile semiconductor memory device according to the fourth embodiment.

FIG. 7B is a top view showing a manufacturing step of the nonvolatile semiconductor memory device according to the fourth embodiment.

FIG. 7C is a top view showing a manufacturing step of the nonvolatile semiconductor memory device according to the fourth embodiment.

FIG. 7D is a top view showing a manufacturing step of the nonvolatile semiconductor memory device according to the fourth embodiment.

FIG. 7E is a top view showing a manufacturing step of the nonvolatile semiconductor memory device according to the fourth embodiment.

FIG. 7F is a top view showing a manufacturing step of the nonvolatile semiconductor memory device according to the fourth embodiment.

FIG. 7G is a top view showing a manufacturing step of the nonvolatile semiconductor memory device according to the fourth embodiment.

FIG. 7H is a top view showing a manufacturing step of the nonvolatile semiconductor memory device according to the fourth embodiment.

FIG. 8A is a top view showing word lines WL according to a fifth embodiment in a peripheral region AR2.

FIG. 8B is a top view showing word lines WL according to the fifth embodiment in a peripheral region AR2.

FIG. 9A is a top view showing a manufacturing step of a nonvolatile semiconductor memory device according to the fifth embodiment.

FIG. 9B is a top view showing a manufacturing step of the nonvolatile semiconductor memory device according to the fifth embodiment.

FIG. 9C is a top view showing a manufacturing step of the nonvolatile semiconductor memory device according to the fifth embodiment.

FIG. 9D is a top view showing a manufacturing step of the nonvolatile semiconductor memory device according to the fifth embodiment.

FIG. 9E is a top view showing a manufacturing step of the nonvolatile semiconductor memory device according to the fifth embodiment.

FIG. 9F is a top view showing a manufacturing step of the nonvolatile semiconductor memory device according to the fifth embodiment.

FIG. 9G is a top view showing a manufacturing step of the nonvolatile semiconductor memory device according to the fifth embodiment.

FIG. 9H is a top view showing a manufacturing step of the nonvolatile semiconductor memory device according to the fifth embodiment.

### DETAILED DESCRIPTION

A nonvolatile semiconductor memory device according to one embodiment includes a first region, a second region, and a plurality of word lines. The first region includes a plurality of electrically-rewritable memory transistors. The second region is located around the first region. The plurality of word lines are connected to the gates of the plurality of memory transistors respectively. The plurality of word lines include interconnection portions and connection portions respectively. The interconnection portions extend in a first direction to head from the first region to the second region, and are arrayed in a second direction orthogonal to the first direction with a first distance therebetween. The connection portions are extending from the interconnection portions, located in the second region, and electrically connected to contacts, respectively. The ends of the plurality of connection portions are formed along straight lines extending in the second direction.

A nonvolatile semiconductor memory device according to one embodiment includes a first region, a second region, and a plurality of word lines. The first region includes a plurality of electrically-rewritable memory transistors. The second region is located around the first region. The plurality of word lines are connected to the gates of the plurality of memory transistors respectively. The plurality of word lines include interconnection portions and connection portions respectively. The interconnection portions extend in a first direction to head from the first region to the second region, and are arrayed in a second direction orthogonal to the first direction with a first distance therebetween. The connection portions are extending from the interconnection portions, located in the second region, and electrically connected to contacts, respectively. The plurality of connection portions include a plurality of connection portion pairs each of which is a pair of connection portions. Each of the plurality of connection portion pairs is formed such that ends of the connection portions are along a straight line extending in the first direction. The plurality of connection portion pairs have their ends located at different positions in the second direction.

According to a method of manufacturing a nonvolatile semiconductor memory device according to one embodiment, a first mask is first formed above a conducting layer. Then, a second mask having a first pattern is formed above the first mask. Then, a first side wall film is formed on the side walls of the second mask. Then, the second mask is removed while leaving the first side wall film. Then, a third mask having a larger width than that of the first side wall film is formed above the first side wall film. Then, such portions of the first mask as are not covered by the first side wall film and the third mask are removed so that the first mask is processed into a loop shape. Then, the first side wall film and the third mask are removed. Then, a second side wall film is formed on the side walls of the first mask, and the first mask is removed while leaving the second side wall film. Then, a fourth mask having a larger width than that of the second side wall film is formed above the second side wall film. Then, such portions of the conducting layer as are not covered by the second side wall film and the fourth mask are removed so that the conducting layer is processed into a loop shape. Then, the conducting layer is partially removed to be processed such that the loop shape is destroyed.

One embodiment of a nonvolatile semiconductor memory device will be explained below with reference to the drawings.

### First Embodiment

### Configuration

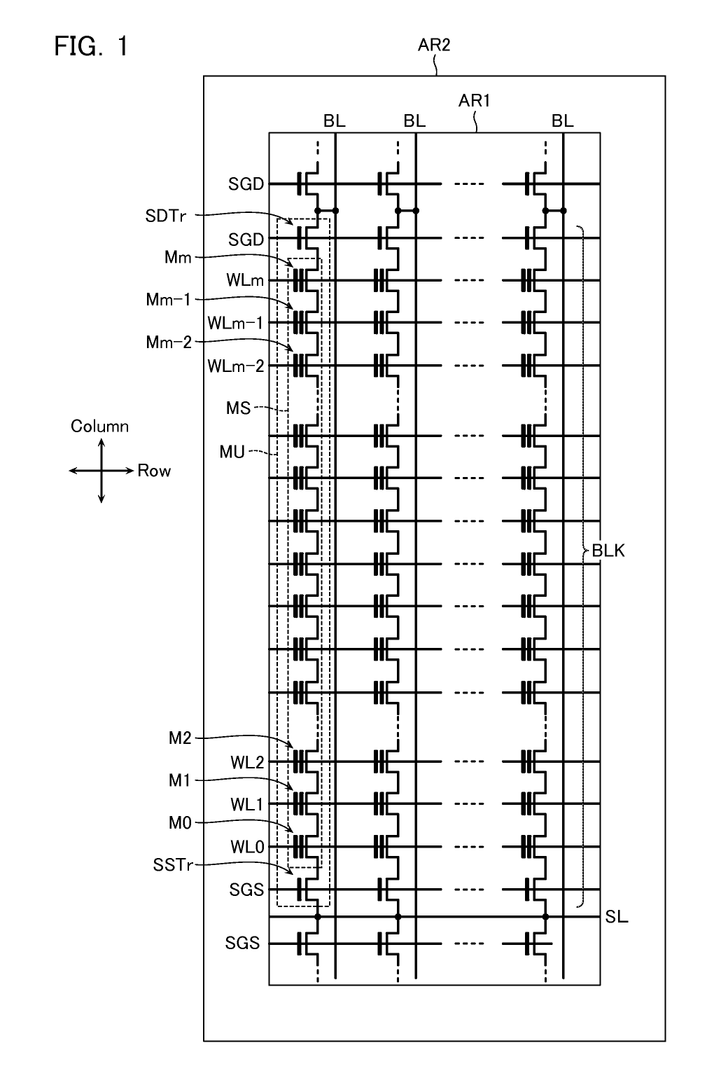

First, the configuration of a nonvolatile semiconductor memory device according to a first embodiment will be explained with reference to FIG. 1. FIG. 1 is a circuit diagram showing a nonvolatile semiconductor memory device according to the first embodiment.

As shown in FIG. 1, the nonvolatile semiconductor memory device according to the first embodiment includes a memory region AR1 including memory transistors M0 to Mm for storing data, and a peripheral region AR2 provided around the memory region AR1. A control circuit for controlling the memory transistors M0 to Mm, and the like are formed on the peripheral region AR2.

As shown in FIG. 1, the memory region AR1 includes memory blocks BLK as units of data erasing. A memory block BLK includes a plurality of memory units MU. A memory unit MU includes a memory string MS, a source-side select transistor SSTr, and a drain-side select transistor SDTr. Memory units MU are arrayed in a row direction and a column direction in a matrix formation.

As shown in FIG. 1, a memory string MS is configured by memory transistors M0 to Mm connected in series. Hereinafter, where it is unnecessary to make a reference to any specific one of the memory transistors M0 to Mm, they are to be generically referred to as memory transistors M. The memory transistors M retain data by accumulating charges in their charge accumulation layers.

Word lines WL0 to WLm are connected to the gates of the memory transistors M0 to Mm. Hereinafter, where it is unnecessary to make a reference to any specific one of the word lines WL0 to WLm, they are to be generically referred to as word lines WL. The word lines WL are formed across the memory region AR1 and the peripheral region AR2, and the ends of the word lines WL are located in the peripheral region AR2.

The drain of the source-side select transistor SSTr is connected to the source side of the memory string MS (or the source of the memory transistor M0). A source-side select gate line SGS is connected to the gate of the source-side select transistor SSTr. The source of the source-side select transistor SSTr is connected to a source line SL.

The source of the drain-side select transistor SDTr is connected to the drain side of the memory string MS (or the drain of the memory transistor Mm). A drain-side select gate line SGD is connected to the gate of the drain-side select transistor SDTr. The drain of the drain-side select transistor SDTr is connected to a bit line BL.

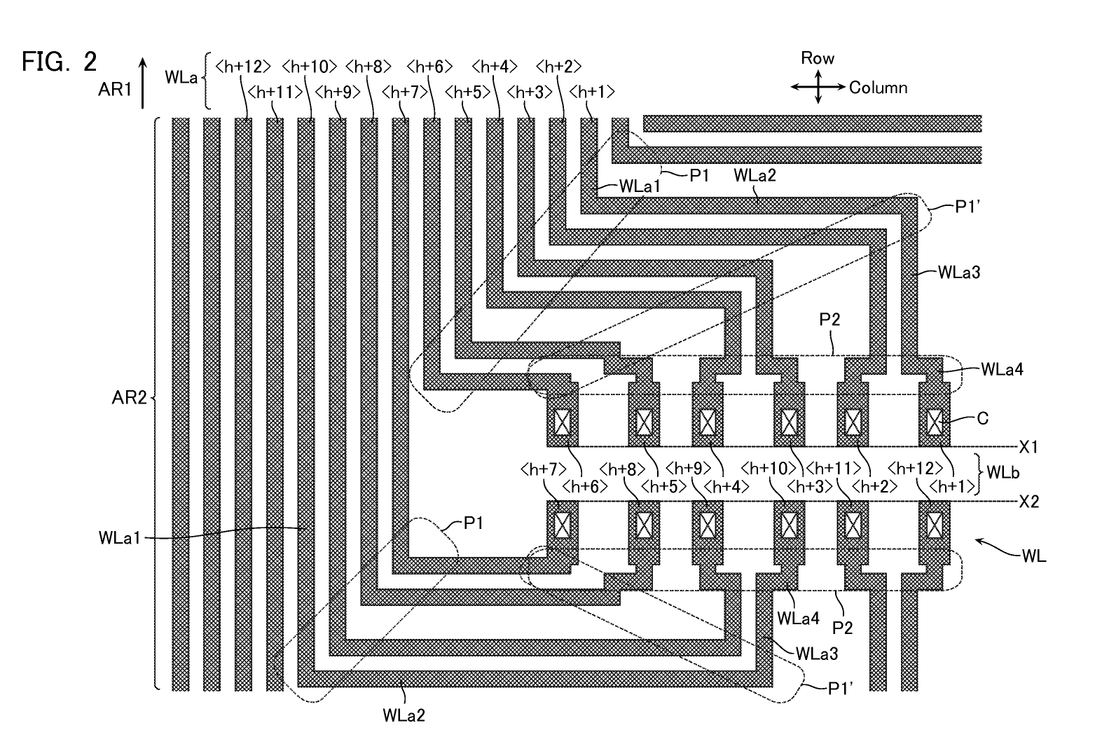

Next, the shape of the word lines WL in the peripheral region AR2 will be explained with reference to FIG. 2. FIG. 2 is a top view of the word lines WL in the peripheral region AR2.

As shown in FIG. 2, the word lines WL have interconnection portions WLa and connection portions WLb. Generally, one memory unit MU includes a two's power number of memory transistors M (for example, 2⁶−=64 memory transistors). FIG. 2 shows the shapes of a two's power number of interconnection portions WLa and connection portions WLb extending from one memory unit MU. However, in order to avoid complicating the illustration, FIG. 2 shows in a simplified manner, only interconnection portions WLa<h+1> to WLa<h+12> located at (h+1)th to (h+12)th orders as counted in the column direction and connection portions WLb<h+1> to WLb<h+12> extending from their ends, which are part of the two's power number of interconnection portions WLa and connection portions WLb (where h is a natural number).

The interconnection portions WLa extend in the row direction (a direction parallel with a substrate) from the memory region AR1 to the peripheral region AR2, and are arrayed in the column direction (a direction parallel with the substrate and orthogonal to the row direction) with a certain pitch between them. The interconnection portions WLa<h+1> to WLa<h+12> are bent by approximately 90 degrees in regions P1, P1′, and P2 in the peripheral region AR2. That is, the interconnection portions WLa<h+1> to WLa<h+12> each have a first base portion WLa1, a second base portion WLa2, and a third base portion WLa3. The first base portion WLa1 extends in the row direction across the memory region AR1 and the peripheral region AR2 and has one end in the peripheral region AR2. The second base portion WLa2 extends in the column direction with one end thereof contacting the one end of the first base portion WLa1. The third base portion WLa3 extends in the row direction with one end thereof contacting the other end of the second base portion WLa2. The interconnection portions WLa<h+1> to WLa<h+5> and WLa<h+8> to WLa<h+12> each have a fourth base portion WLa4 having an L shape extending in the column direction and the row direction. The end of such a portion of the fourth base portion WLa4 as extending in the column direction is connected to the other end of the third base portion WLa3.

In FIG. 2, the interconnection portions WLa<h+1> to WLa<h+12> are connected to the gates of the memory transistors M provided in a common memory string MS respectively. In order to save the occupation area required for the word lines WL, it is preferable that the other interconnection portions WLa omitted from illustration be bent by approximately 90 degrees in the regions P1, P1′, and P2 likewise. The positions in the regions P1 at which the interconnection portions WLa are bent by approximately 90 degrees are referred to as bending positions . The length from the boundary between the memory region AR1 and the peripheral region AR2 to the bending positions is longer than the quadruple of the width of the interconnection portions WLa.

The connection portions WLb are extending from the interconnection portions WLa, and located in the peripheral region AR2, respectively. More specifically, the connection portions WLb are located at the other end side of the third base portions WLa3 of the interconnection portions WLa. The connection portions WLb<h+6> and WLb<h+7> are connected to the other end of the third base portions WLa3 of the interconnection portions WLa<h+6> and WLa<h+7>. The connection portions WLb<h+1> to WLb<h+5> and WLb<h+8> to WLb<h+12> are connected to the ends of such portions of the fourth base portions WLa4 of the interconnection portions WLa<h+1> to WLa<h+5> and WLa<h+8> to WLa<h+12> as extending in the row direction. This connection provides substantially equal intervals between the connection portions WLb in the column direction. In this way, by providing no fourth base portions WLa4 at the connection portions WLb located at the innermost side (the side opposite to the side to which the interconnection portions WLa are bent in the regions P1), it is possible to save the occupation area of the word lines WL in the row direction. Note that it is also possible to provide fourth base portions WLa4 at the connection portions WLb<h+6> and WLb<h+7> like at the connection portions WLb<h+1> to WLb<h+5> and WLb<h+8> to WLb<h+12>.

The connection portions WLb are electrically connected to upper interconnection lines (unillustrated) through contacts C extending in a stacking direction. The connection portions WLb are formed in a rectangular shape extending in the row direction. The upper interconnection lines are provided in a layer above the word lines WL. The width of the connection portions WLb is larger than the width of the interconnection portions WLa. The distance between the connection portions WLb is larger than the distance between the interconnection portions WLa. Here, a width is a dimension in the direction orthogonal to the direction in which the interconnection lines (or portions thereof) extend. For example, the width of the connection portions WLb is the dimension in the column direction orthogonal to the direction (row direction) in which the connection portions WLb extend. The distance between the interconnection portions WLa refers to the minimum distance between the interconnection portions WLa arranged at regular intervals in the column direction. The distance between the connection portions WLb refers to the distance between such connection portions WLb as are adjoining each other in the column direction in the peripheral region AR2.

The ends of the connection portions WLb<h+1> to WLb<h+6> are arranged along a straight line extending in the column direction. Specifically, the ends of the connection portions WLb<h+1> to WLb<h+6> are arranged in parallel with a straight line X1 extending in the column direction. The connection portions WLb<h+1> to WLb<h+6> are provided in a region closer to the memory region AR1 than the straight line X1 is. Other connection portions WLb omitted from illustration may be arranged in parallel with the straight line X1 together with the illustrated connection portions WLb<h+1> to WLb<h+6> or may be arranged according to another regularity. For example, when there are 64 memory transistors M in one memory unit, 32 connection portions WLb are arranged in parallel with the straight line X1. FIG. 2 shows only 6 out of the 32 connection portions WLb as representatives.

The ends of the connection portions WLb<h+7> to WLb<h+12> are arranged along a straight line extending in the column direction. Specifically, the ends of the connection portions WLb<h+7> to WLb<h+12> are arranged in parallel with a straight line X2 extending in the column direction. The connection portions WLb<h+7> to WLb<h+12> are arranged in a region farther from the memory region AR1 than the straight line X2 is therefrom. The straight line X1 is closer to the memory region AR1 than the straight line X2 is. Other connection portions WLb omitted from illustration may be arranged in parallel with the straight line X2 together with the illustrated connection portions WLb<h+7> to WLb<h+12> or may be arranged according to another regularity. For example, when there are 64 memory transistors M in one memory unit, 32 connection portions WLb are arranged in parallel with the straight line X2. FIG. 2 shows only 6 out of the 32 connection portions WLb as representatives.

In this way, the connection portions WLb<h+1> to WLb<h+6> are arranged oppositely to the connection portions WLb<h+7> to WLb<h+12> in the row direction. Specifically, the connection portions WLb<h+1> to WLb<h+6> are arranged symmetrically with the connection portions WLb<h+7> to WLb<h+12> in the row direction.

Here, the plurality of word lines WL (interconnection portions WLa) are arrayed in the column direction, and end portions of the plurality of interconnection portions WLa that are beyond the regions P1 are bent to the column direction sequentially. Therefore, in the peripheral region AR2, a large space is generated in the column direction side of the region P1. The first embodiment can save the occupation area of the word lines WL by arranging the connection portions WLb in this large space efficiently.

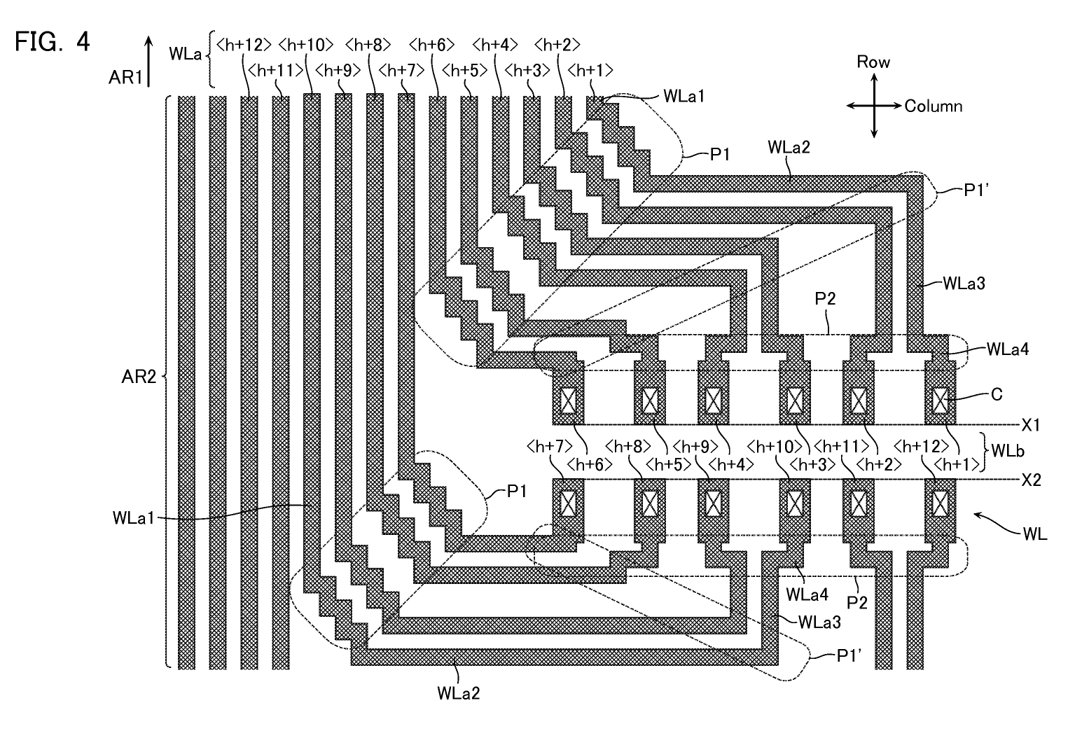

Specifically, the connection portions WLb are arranged in the large space shown in FIG. 2, by being positioned after the interconnection portions WLa have been first bent to the column direction and then to the row direction. This enables to shorten the length of the word lines WL in the row direction. For example, the first embodiment can reduce the occupation area of the word lines WL to approximately 65% or lower as compared with FIG. 4A, FIG. 10, and FIG. 11 of Patent Document 1. That is, the first embodiment can save the occupation area of the nonvolatile semiconductor memory device.

By utilizing the large space, it is possible to make the distance between the connection portions WLb larger than the distance between the interconnection portions WLa. Likewise, it is possible to make the width of the connection portions WLb larger than the width of the interconnection portions WLa. This ensures secure provision of contacts C at the connection portions WLb.

Such a layout can be manufactured by conventional lithography techniques. However, applying a double side-wall process to be described later enables to manufacture a miniaturized nonvolatile semiconductor memory device.

[Manufacturing Method]

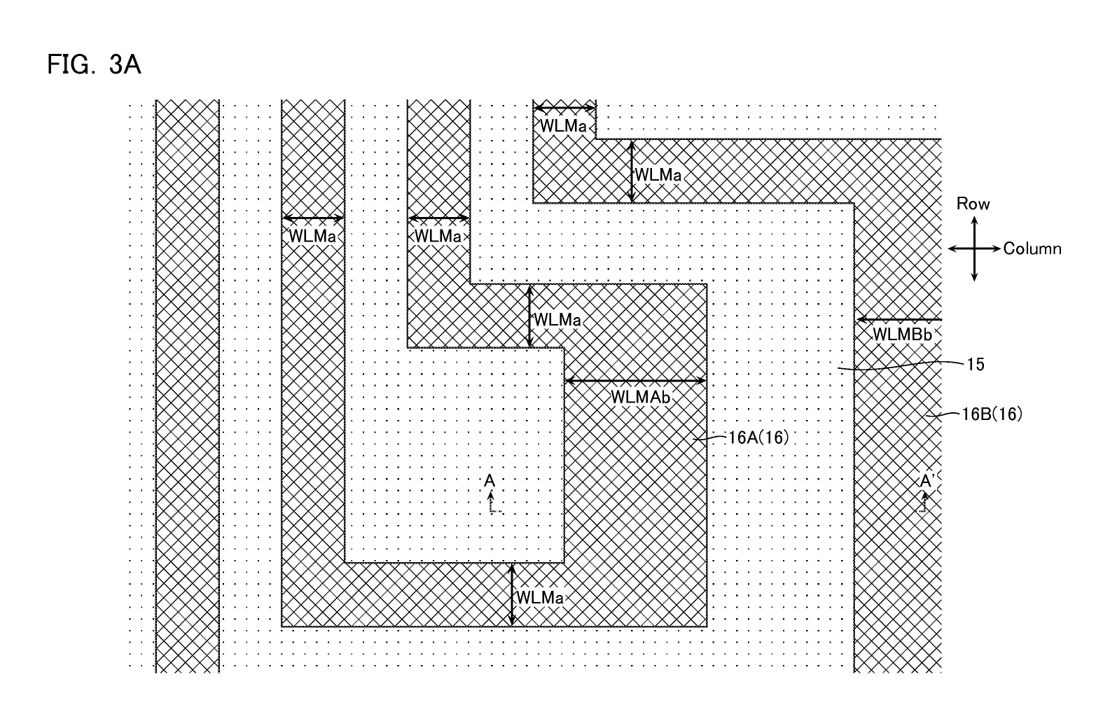

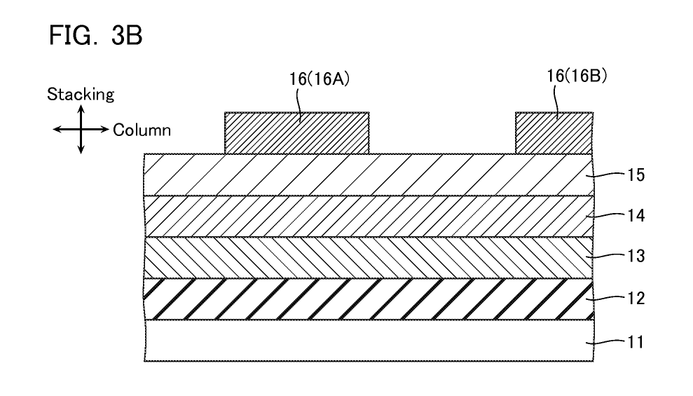

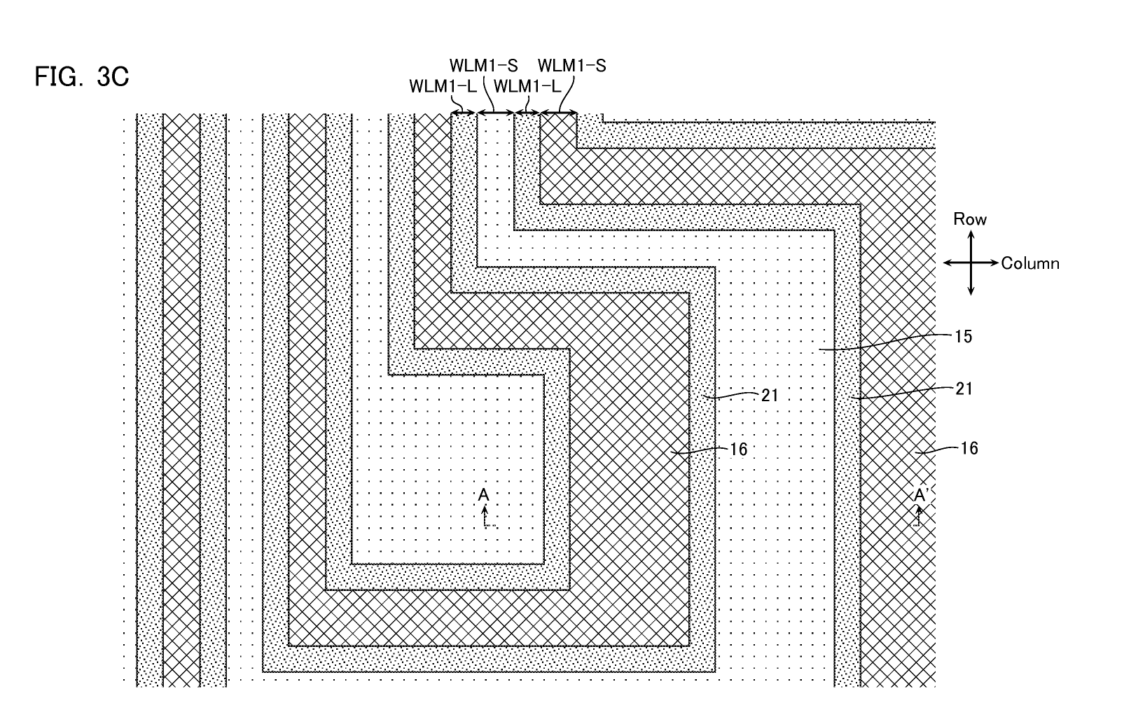

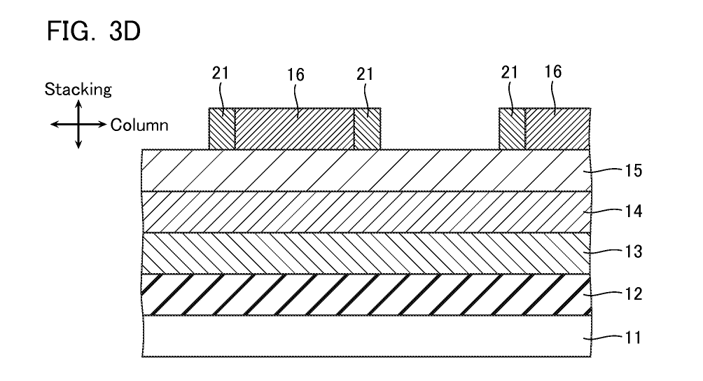

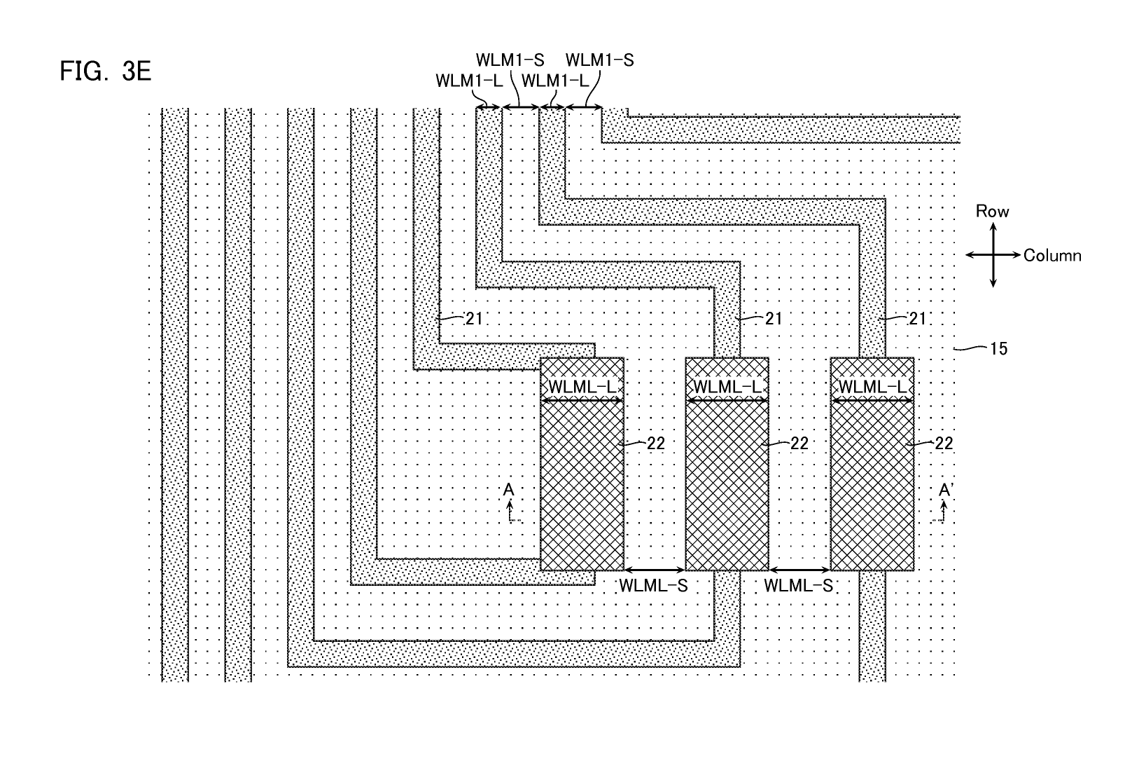

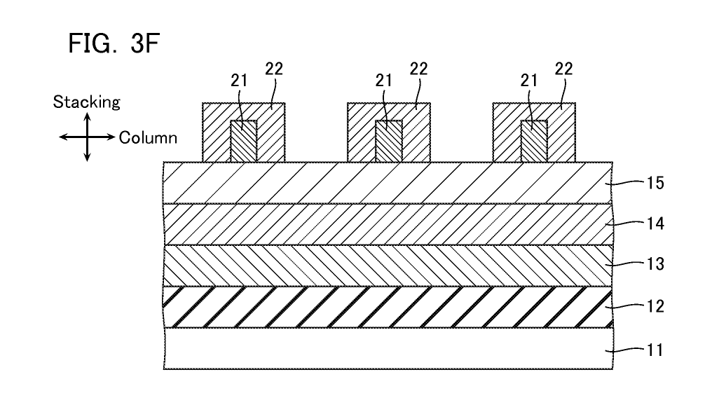

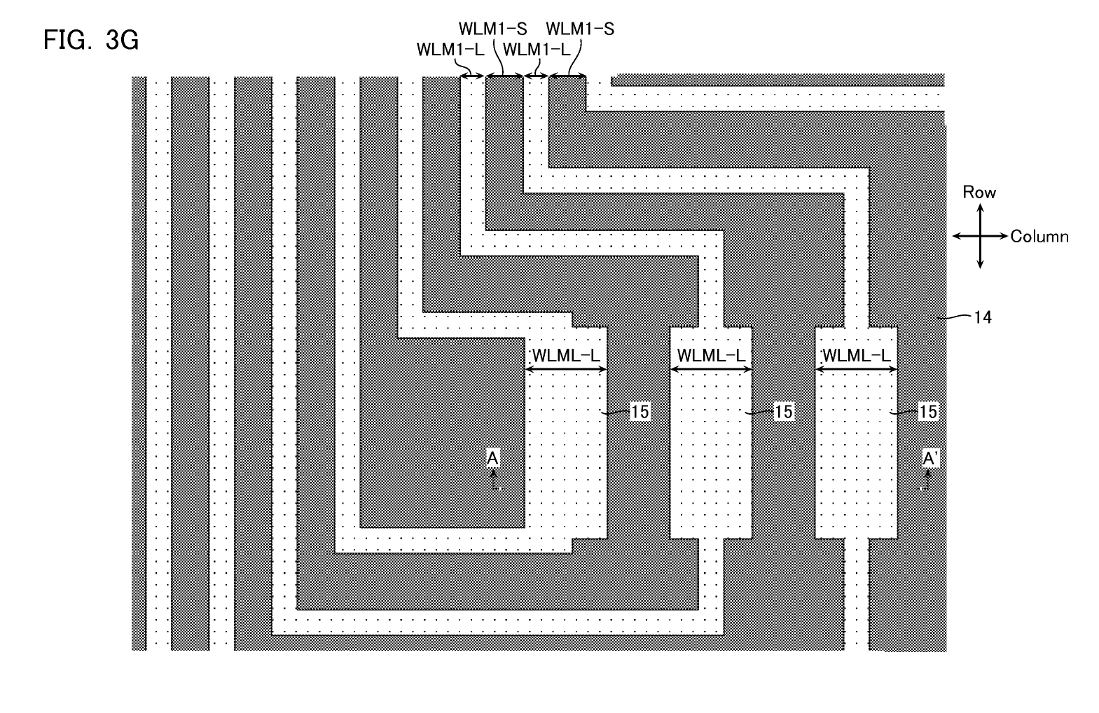

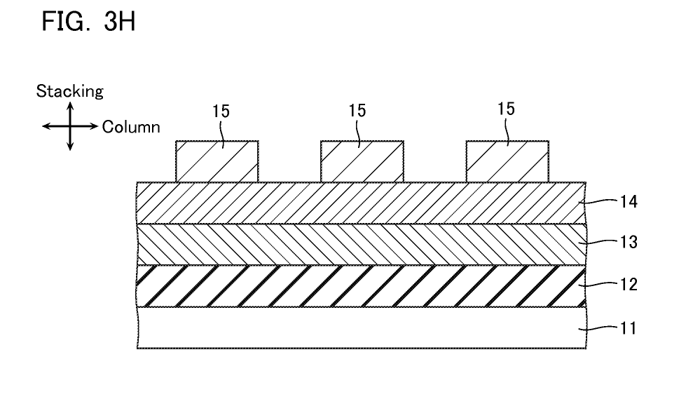

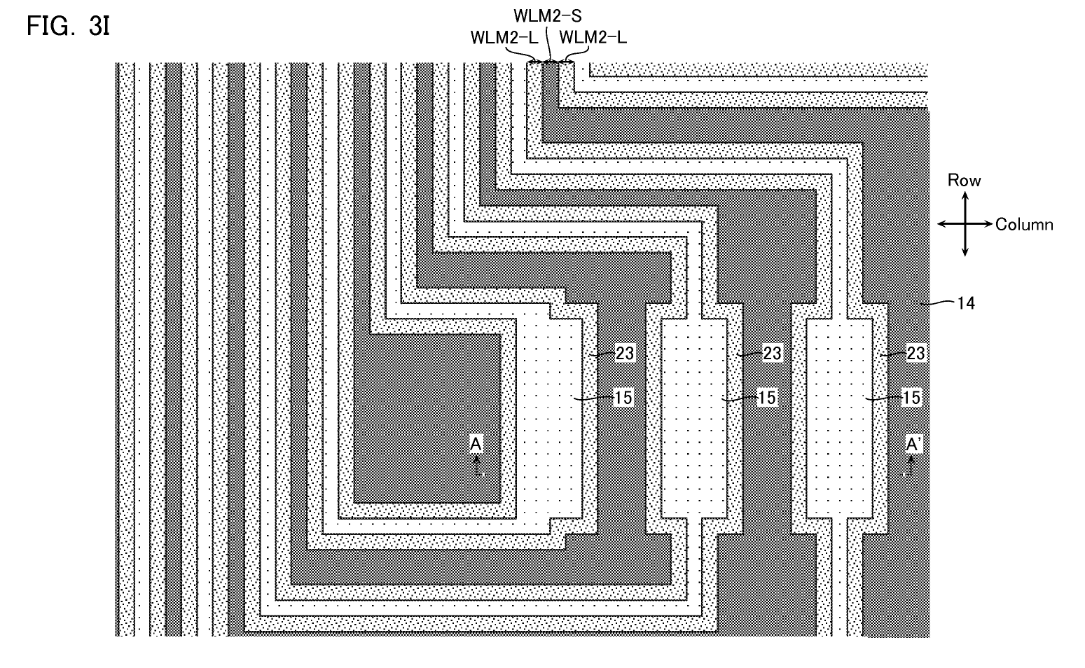

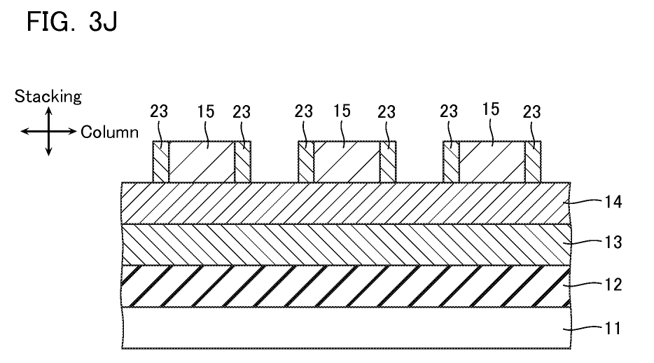

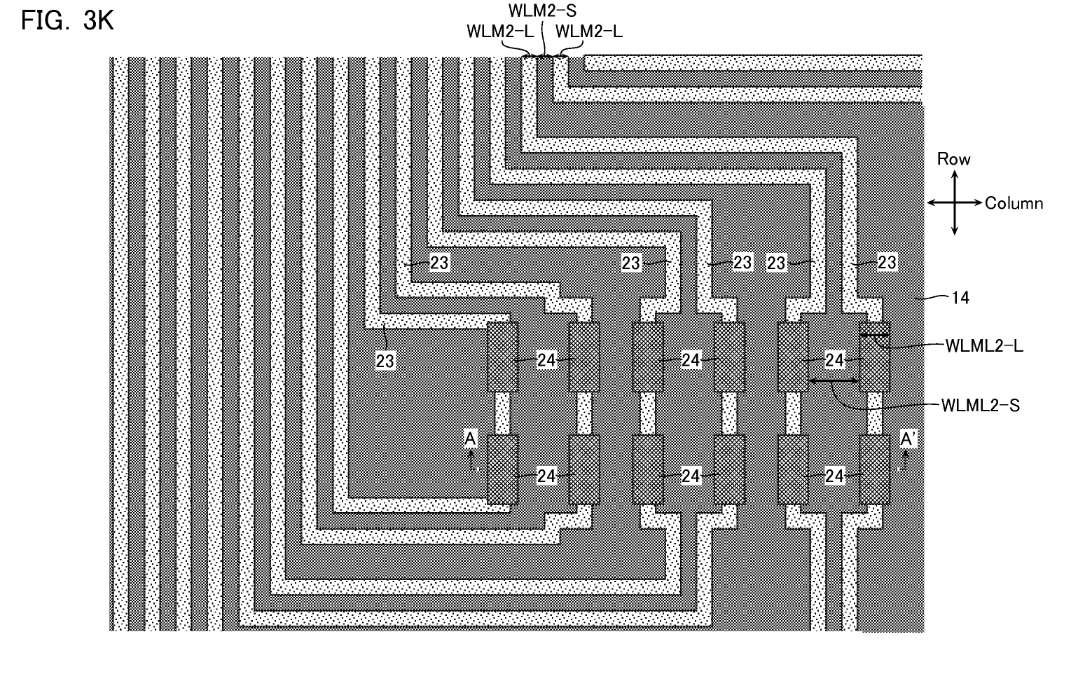

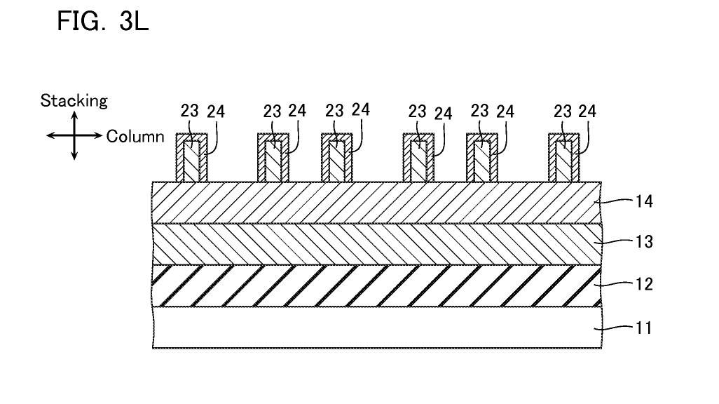

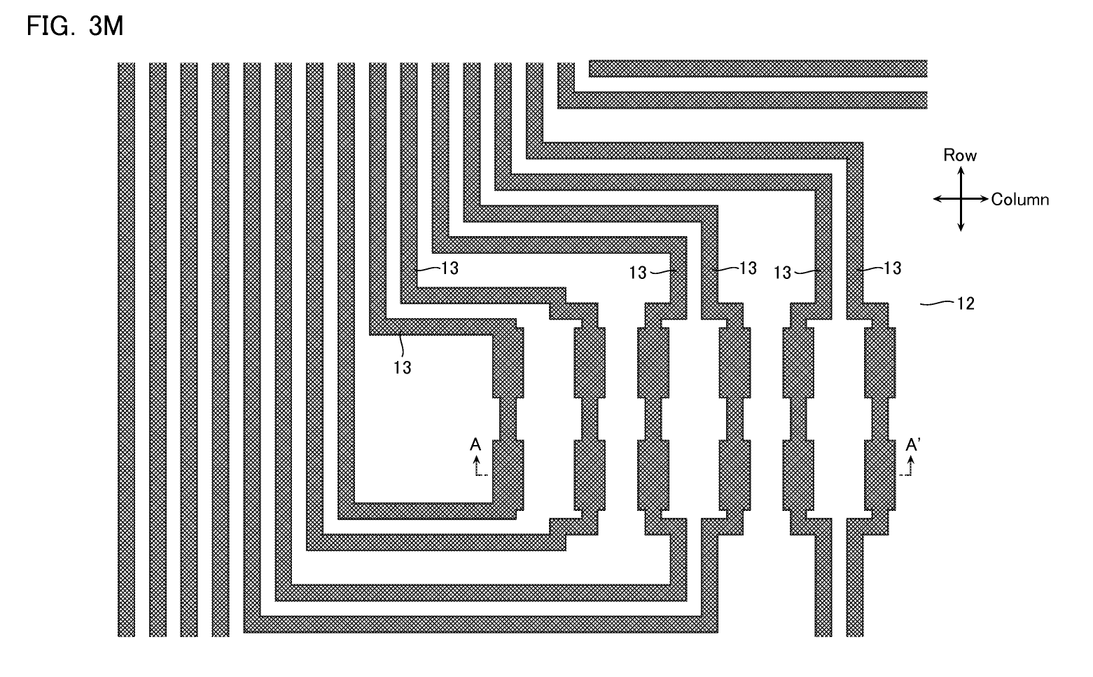

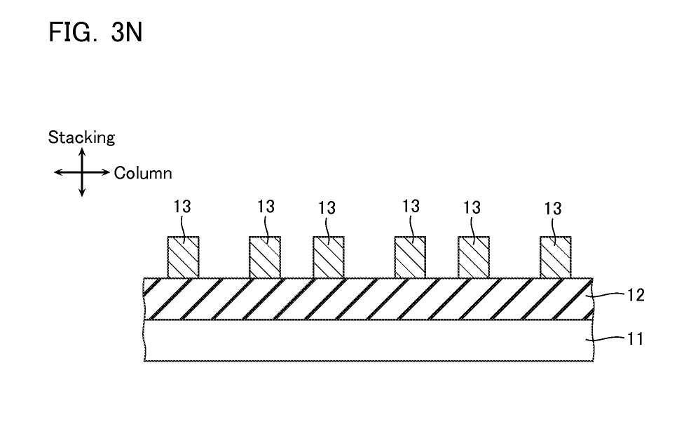

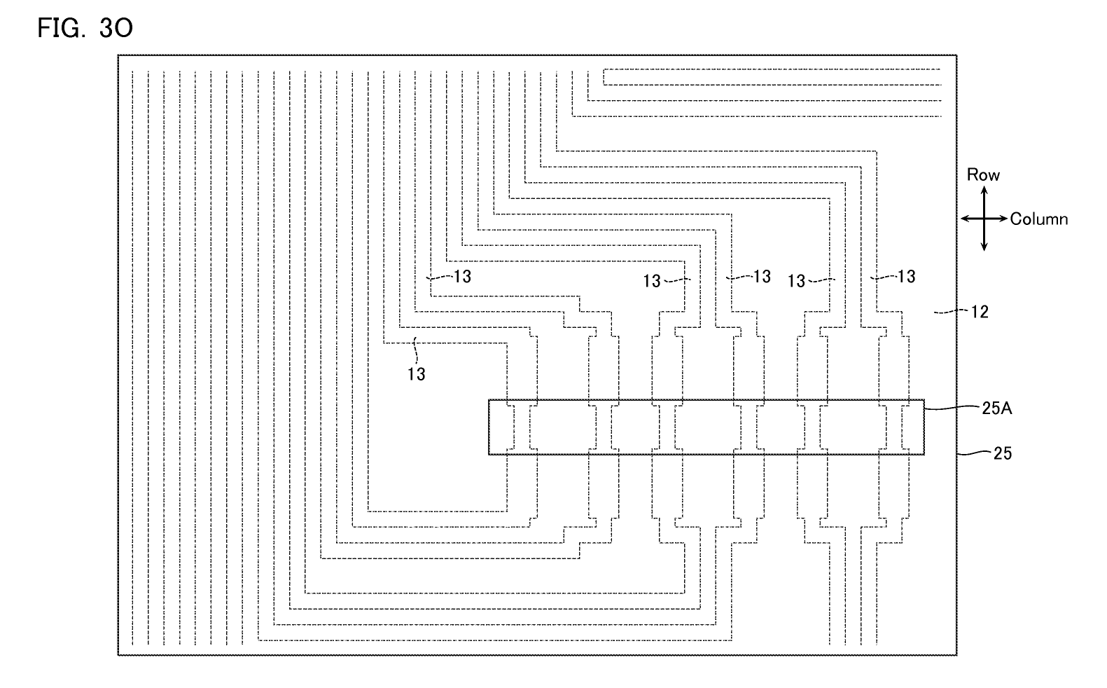

Next, a method of manufacturing the word lines WL according to the first embodiment will be explained with reference to FIG. 3A to FIG. 3O. For example, the word lines WL are formed by a double side-wall process. FIG. 3A, FIG. 3C, FIG. 3E, FIG. 3G, FIG. 3I, FIG. 3K, FIG. 3M, and FIG. 3O are top views observed in the manufacturing process. FIG. 3B, FIG. 3D, FIG. 3F, FIG. 3H, FIG. 3J, FIG. 3L, and FIG. 3N are cross-sectional views of FIG. 3A, FIG. 3C, FIG. 3E, FIG. 3G, FIG. 3I, FIG. 3K, and FIG. 3M as taken along a line A-A′.

As shown in FIG. 3A and FIG. 3B, an insulating layer 12, a conducting layer 13, a protecting layer 14, a first mask layer 15, and a second mask layer 16 are formed above a semiconductor substrate 11 sequentially. The second mask layer 16 is formed above the first mask layer 15 in a certain pattern. Specifically, the second mask layer 16 includes an L-shaped layer 16A having a hollow when seen from above, and a layer 16B enclosing the layer 16A with a certain pitch from the layer 16A, as shown in FIG. 3A. That is, the layer 16B has a loop shape enclosing the layer 16A. A width WLMa of the layer 16A and layer 16B is the minimum resolution limit of the lithography technologies. The layer 16A extends in the row direction by having the width WLMa, bends at a certain position to the column direction by having the width WLMa, and then further bends to the row direction by having a width WLMAb larger than the width WLMa. The layer 16B extends in the row direction by having the width WLMa, bends at a certain position to the column direction by having the width WLMa, and then further bends to the row direction by having a width WLMBb larger than the width WLMa. The conducting layer 13 will be processed into the word lines WL through steps to be described later.

As shown in FIG. 3C and FIG. 3D, after the second mask layer 16 is slimmed, a first side wall film 21 is formed on the side walls of the second mask layer 16. Here, the first side wall film 21 is formed continuously on the side walls of the second mask layer 16 to form a closed loop structure. The width WLM1-L of the first side wall film 21 is approximately twice as large as the width of the interconnection portions WLa. In a region where the first side wall film 21 is arranged at regular intervals, the distance WLM1-S between the first side wall film 21 at one position and the first side wall film 21 at an adjoining position is substantially equal to the width WLM1-L of the first side wall film 21.

As shown in FIG. 3E and FIG. 3F, wet etching is carried out to remove the second mask layer 16 but to leave the first side wall film 21 based on an etching selectivity between the second mask layer 16 and the first side wall film 21. Then, resists 22 are formed to cover some portions of the first side wall film 21. The resists 22 have a rectangular shape extending in the row direction, and are arranged to adjoin each other in the column direction. The resists 22 are formed about the regions where the connection portions WLb are to be formed later. At this time, in order to provide the resists 22 with a stable shape, it is preferable to arrange the resists 22 at regular intervals with the same size. That is, it is preferable to arrange the resists 22 such that the row-direction ends thereof are in parallel with straight lines extending in the column direction. The width WLML-L of the resists 22 is formed larger than the width WLM1-L and distance WLM1-S of the first side wall film 21. The resists 22 are to be used when forming the regions P2 of the interconnection portions WLa later. The distance WLML-S between the resists 22 adjoining in the column direction is formed larger than the width WLM1-L and distance WLM1-S of the first side wall film 21.

As shown in FIG. 3G and FIG. 3H, dry etching is carried out by using the first side wall film 21 and the resists 22 as masks. As a result, such portions of the first mask layer 15 as are not covered by the first side wall film 21 and the resists 22 are removed, and hence the first mask layer 15 is processed into a loop shape. A width WLML-L of such portions of the first mask layer 15 as correspond to where the resists 22 were formed is formed larger than a width WLM1-L of the other portions of the first mask layer 15.

As shown in FIG. 3I and FIG. 3J, a second side wall film 23 is formed on the side walls of the first mask layer 15. The second side wall film 23 is formed continuously on the side walls of the first mask layer 15 to form a closed loop structure. The width WLM2-L of the second side wall film 23 is substantially equal to the width of the interconnection portions WLa. In a region where the second side wall film 23 is arranged at regular intervals, the distance WLM2-S between the second side wall film 23 at one position and the second side wall film 23 at an adjoining position is substantially equal to the width WLM2-L of the second side wall film 23. The regions P2 of the interconnection portions WLa will be formed where an end portion of the first side wall film 21 and the resists 22 were formed contacting each other (see FIG. 3E).

As shown in FIG. 3K and FIG. 3L, wet etching is carried out to remove the first mask layer 15 but to leave the second side wall film 23 based on an etching selectivity between the first mask layer 15 and the second side wall film 23. Then, resists 24 are formed to cover some portions of the second side wall film 23. The resists 24 have a rectangular shape extending in the row direction, and are formed about the regions where the connection portions WLb are to be formed later. At this time, in order to provide the resists 24 with a stable shape, it is preferable to arrange the resists 24 at regular intervals with the same size. That is, it is preferable to arrange the resists 24 in a matrix formation. The width WLML2-L of the resists 24 is formed substantially equal to the width of the connection portions WLb and larger than the width WLM2-L and distance WLM2-S of the second side wall film 23. The distance WLML2-S between such resists 24 as are located on both sides of the first mask layer 15, which was removed, and as are adjoining in the column direction is formed larger than the width WLM2-L and distance WLM2-S of the second side wall film 23.

As shown in FIG. 3M and FIG. 3N, dry etching is carried out by using the second side wall film 23 and the resists 24 as masks. As a result, such portions of the protecting layer 14 as are not covered by the second side wall film 23 and the resists 24 and such portions of the conducting layer 13 as are located under these portions are removed, and hence the protecting layer 14 and the conducting layer 13 are processed into a loop shape. After this processing, the protecting layer 14 is removed.

As shown in FIG. 3O, a resist 25 for covering the conducting layer 13 is formed. The resist 25 has a linear window 25A extending in the column direction. After this, etching is carried out to such portions of the conducting layer 13 as are exposed through the window 25A to process the conducting layer 13 so as to destroy its loop structure. In this way, the resist 25 having the linear window 25A enables minute processing, allowing the connection portions WLb to be formed with precision.

Through the steps shown in FIG. 3A to FIG. 3O, the conducting layer 13 is processed into the shape of the word lines WL according to the first embodiment. As a result, the ends of the connection portions WLb become parallel with straight lines extending in the column direction. Moreover, the above-described steps can save a space (an empty space) where no word lines WL (interconnection portions WLa and connection portions WLb) are formed, and hence can save the occupation area of the word lines WL.

Furthermore, by applying a double side-wall process, it is possible to manufacture a miniaturized nonvolatile semiconductor memory device. Particularly, by forming the connection portions WLb by using the resists 22 having a larger width than that of the first side wall film 21 and the resists 24 having a larger width than that of the second side wall film 23, it is possible to miniaturize the nonvolatile semiconductor memory device while suppressing the occupation area. Moreover, it is possible to provide contacts C at the connection portions WLb securely.

### Second Embodiment

### Configuration

Next, the configuration of a nonvolatile semiconductor memory device according to a second embodiment will be explained with reference to FIG. 4. Any components of the second embodiment that are the same as the first embodiment will be denoted by the same reference numerals and will not be explained again.

Similar effects to the first embodiment will be achieved by the second embodiment. The second embodiment is different from the first embodiment in the shape of the interconnection portions WLa. In the regions P1 shown in FIG. 4, the first base portions WLa1 of the interconnection portions WLa are bent by approximately 90 degrees plural times, which is the difference from the first embodiment. With these interconnection portions WLa, the second embodiment can stabilize the shape of the interconnection portions WLa in the regions P1 and P2, suppress defects and short-circuits of the word lines WL, and improve the yield ratio.

### Third Embodiment

### Configuration

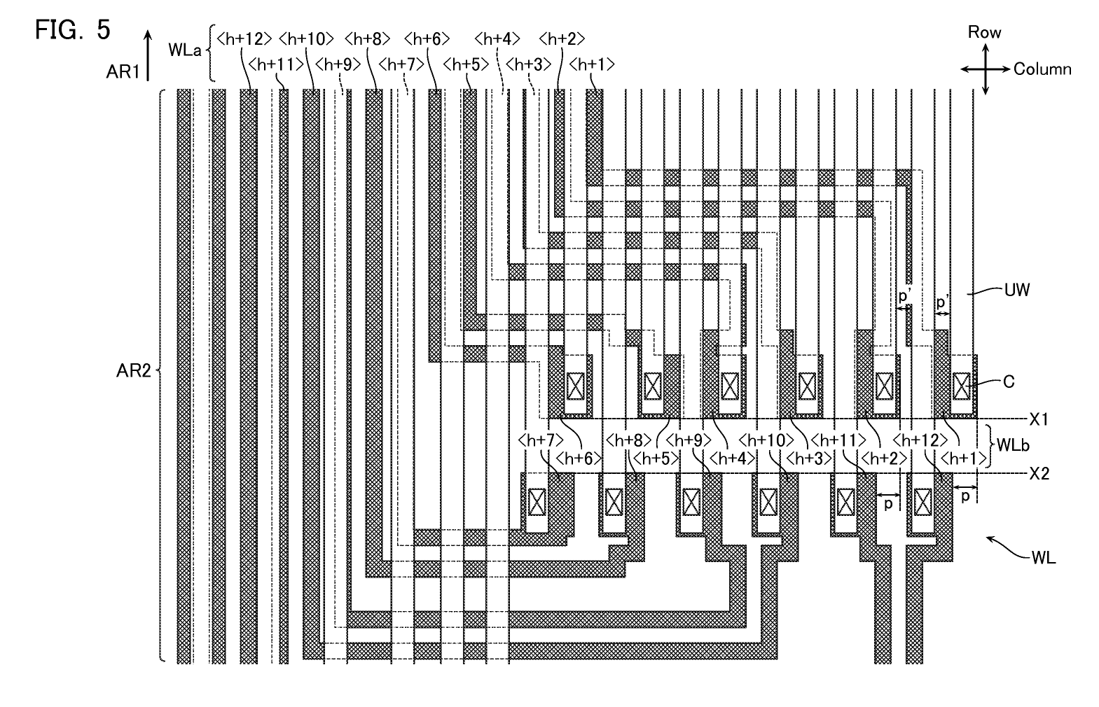

Next, the configuration of a nonvolatile semiconductor memory device according to a third embodiment will be explained with reference to FIG. 5. Any components of the third embodiment that are the same as the first and second embodiments will be denoted by the same reference numerals, and will not be explained again.

The third embodiment is different from the first embodiment in the arrangement of the connection portions WLb. In the third embodiment, the connection portions WLb<h+1> to WLb<h+6> are arranged oppositely to the connection portions WLb<h+7> to WLb<h+12> in the row direction, which is the same as the first embodiment. However, the connection portions WLb are opposed to each other with some misalignment in the column direction corresponding to a pitch p. For example, the connection portion WLb<h+6> and the connection portion WLb<h+7> are misaligned in the column direction by a certain distance. The other connection portions WLb illustrated in FIG. 5 have the same positional relationship. Unillustrated connection portions WLb have the same positional relationship, likewise. In sum, in the third embodiment, among, for example, 64 connection portions WLb for one memory unit MU including 64 memory transistors M, half, i.e., 32 connection portions WLb are arranged oppositely to the remaining 32 connection portions WLb in the row direction, but are misaligned in the column direction by a certain pitch p, to be arranged in a staggered formation.

Furthermore, in the third embodiment, upper interconnection lines UW extend in the row direction and are arrayed in the column direction with a certain pitch p′ between them. The upper interconnection lines UW are electrically connected to the connection portions WLb through contacts C.

To sum up, by arranging the connection portions WLb by misaligning them in the column direction in a staggered formation as described above, the third embodiment enables the upper interconnection lines UW to be arranged in a simple line-and-space pattern. Hence, the third embodiment can facilitate wiring of the upper interconnection lines WL more than the first embodiment. The third embodiment can also suppress defects and short-circuits of the upper interconnection lines UW.

### Fourth Embodiment

### Configuration

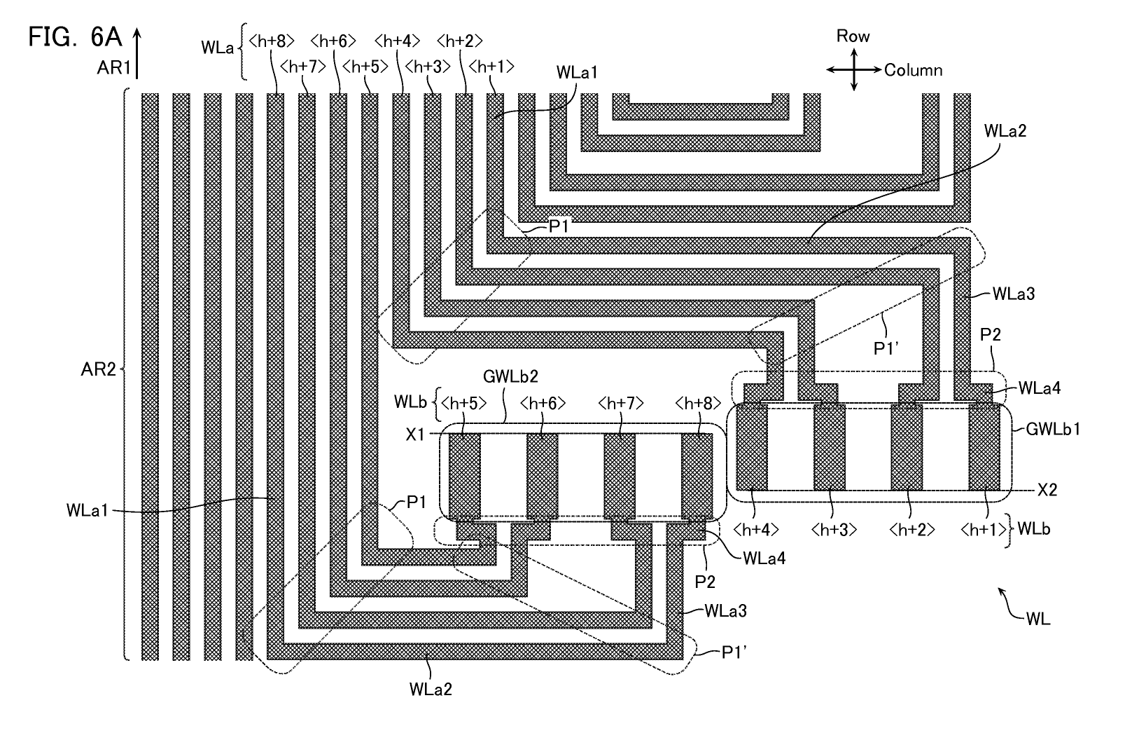

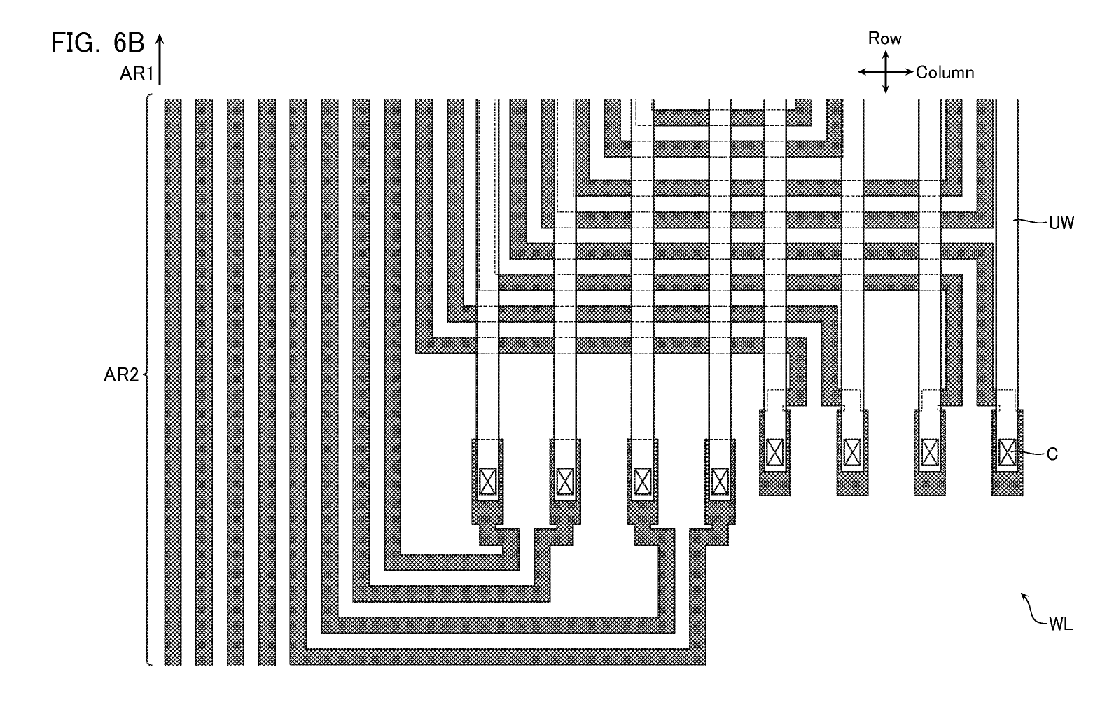

Next, the configuration of a nonvolatile semiconductor memory device according to a fourth embodiment will be explained with reference to FIGS. 6A, 6B. Any components of the fourth embodiment that are the same as the first to third embodiments will be denoted by the same reference numerals and will not be explained again. FIG. 6A shows only interconnection portions WLa<h+1> to WLa<h+8> and connection portions WLb<h+1> to WLb<h+8> in a simplified manner. FIG. 6B shows word lines WL, and upper interconnection lines UW.

The fourth embodiment is different from the first to third embodiments in the arrangement of the connection portions WLb. In the fourth embodiment, the connection portions WLb<h+1> to WLb<h+4> are not arranged oppositely to the connection portions WLb<h+5> to WLb<h+8> in the row direction, which is the difference from the first embodiment. Here, for expediency, the connection portions WLb<h+1> to WLb<h+4> are referred to as a connection portion group GWLb1 and the connection portions WLb<h+5> to WLb<h+8> are referred to as a connection portion group GWLb2.

The ends of the connection portions WLb<h+1> to WLb<h+4> included in the connection portion group GWLb1 and the ends of the connection portions WLb<h+5> to WLb<h+8> included in the connection portion group GWLb2 are positioned along different straight lines extending in the column direction. Specifically, the ends of the connection portions WLb<h+1> to WLb<h+4> are positioned in parallel with a straight line X2, and the ends of the connection portions WLb<h+5> to WLb<h+8> are positioned in parallel with a straight line X1. The connection portion groups GWLb1 and GWLb2 are formed to overlap each other on a certain straight line extending in the column direction. Like in the embodiments described above, unillutstrated connection portions WLb may have the same positional relationship as that of the connection portions WLb<h+1> to WLb<h+8> or may be arranged according to another regularity.

Similar effects to the first embodiment will be achieved by the fourth embodiment. That is, like the first embodiment, the fourth embodiment can save the occupation area of the word lines WL based on the connection portions WLb arranged in a simple pattern described above.

Specifically, the connection portions WLb are arranged in a large space provided in the column direction side of the region P1 shown in FIG. 6A, by being positioned after the interconnection portions WLa have been first bent to the column direction and then to the row direction. This enables to shorten the length of the word lines WL in the row direction. For example, the fourth embodiment can reduce the occupation area of the word lines WL to approximately 65% or lower as compared with FIG. 4A, FIG. 10, and FIG. 11 of Patent Document 1. That is, like the first embodiment, the fourth embodiment can save the occupation area of the nonvolatile semiconductor memory device.

In the first embodiment, the connection portions WLb are arrayed in the column direction and do not adjoin in the row direction. As a result, wiring of upper interconnection lines (corresponding to the upper interconnection lines UW of the third embodiment) can be facilitated in FIG. 6B. Any defects and short-circuits of the upper interconnection lines UW can also be suppressed.

[Manufacturing Method]

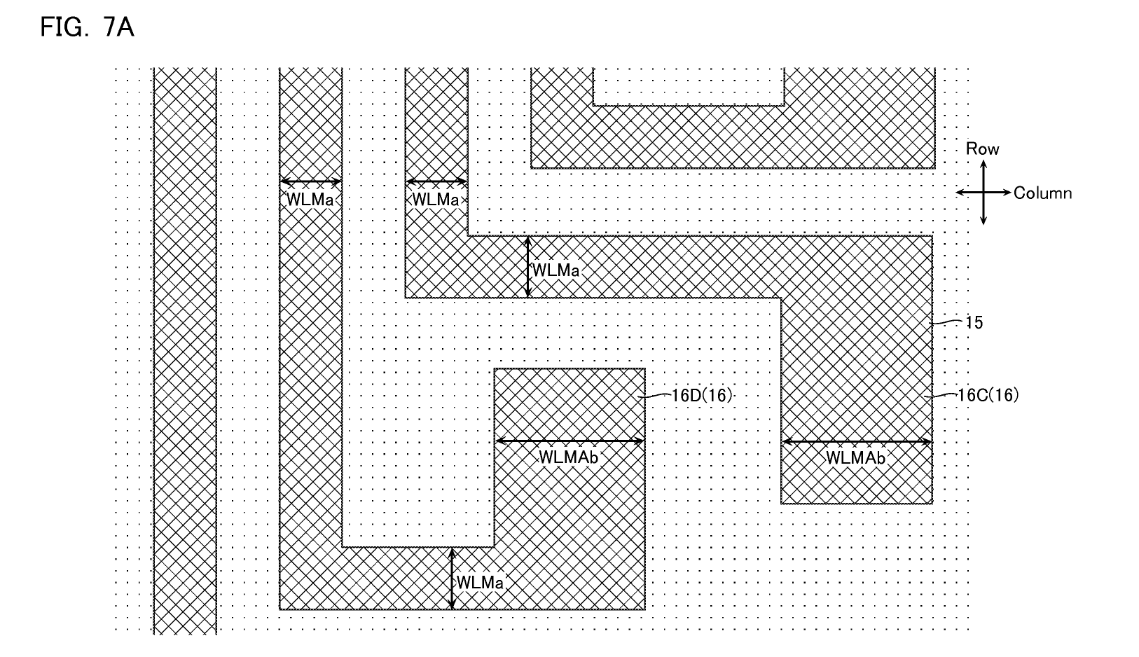

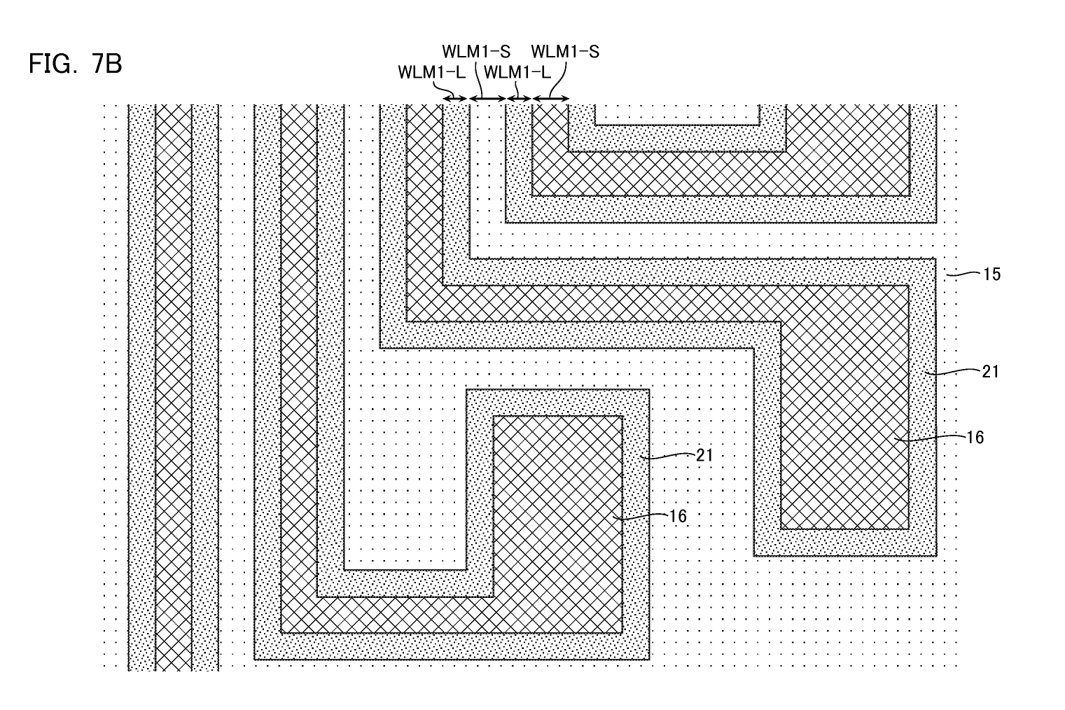

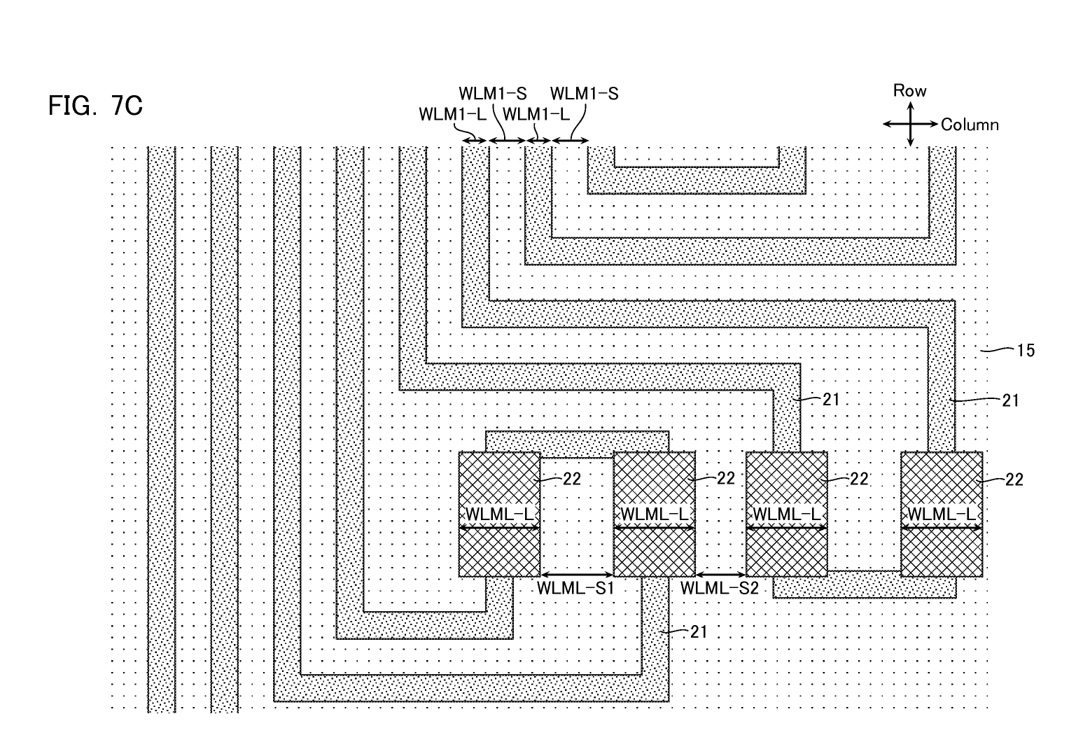

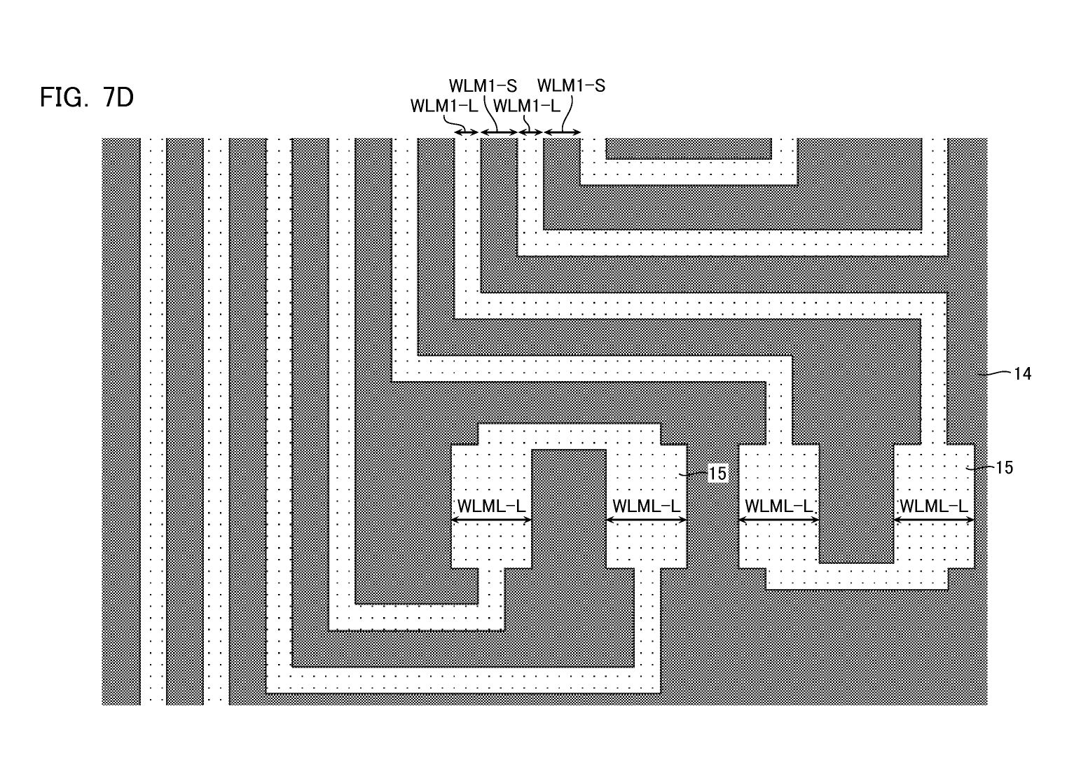

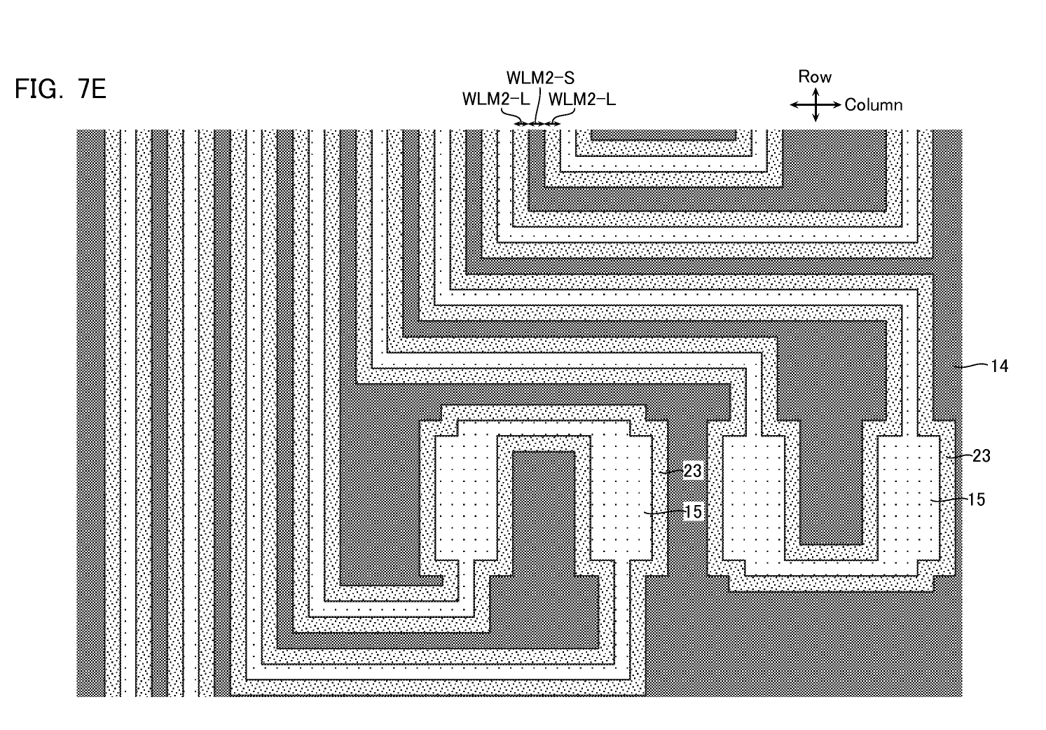

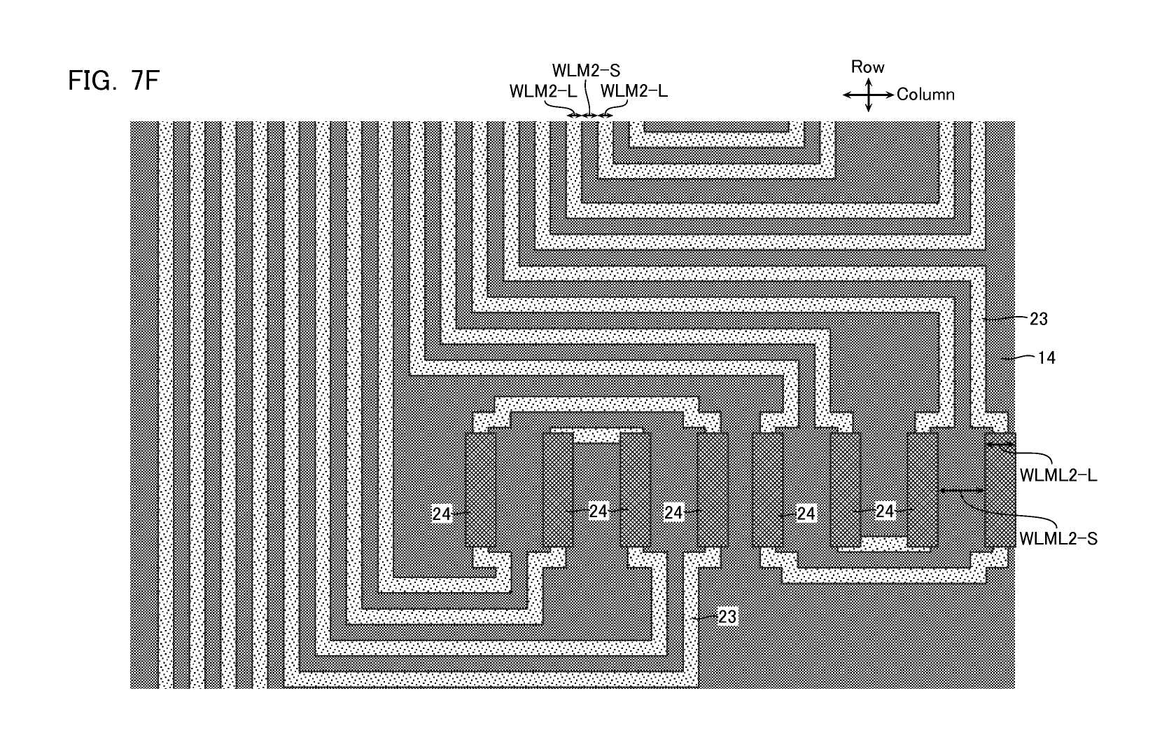

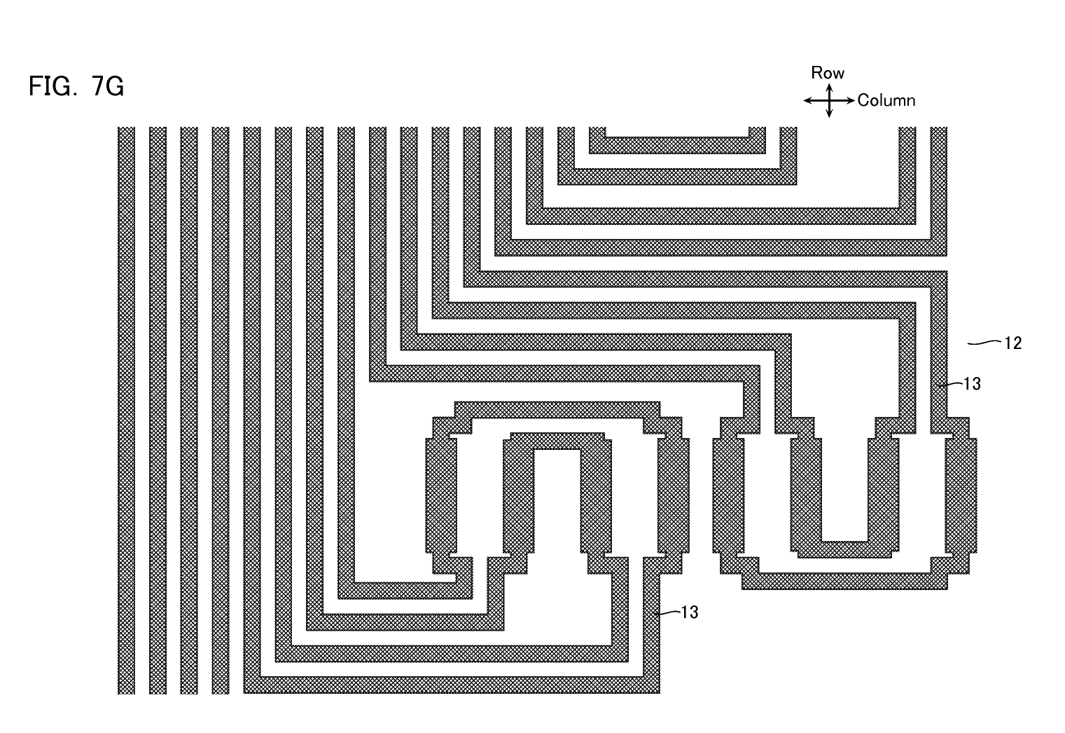

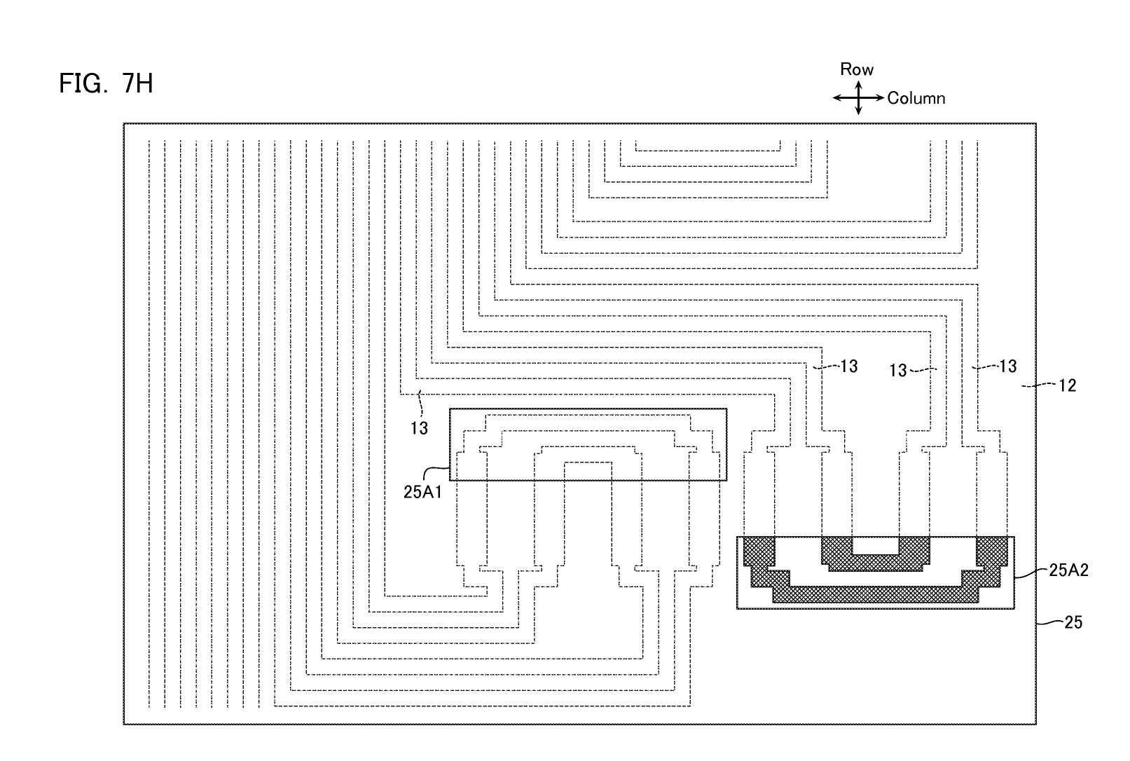

Next, a method of manufacturing the nonvolatile semiconductor memory device according to the fourth embodiment will be explained with reference to FIG. 7A to FIG. 7H. FIG. 7A to FIG. 7H are top views observed in the manufacturing process.

As shown in FIG. 7A, a second mask layer 16 is formed above a first mask layer 15 in a different pattern from that of the first embodiment. Specifically, the second mask layer 16 includes a layer 16C extending in the row direction to go away from the memory region AR1 and a layer 16D extending in the row direction to come close to the memory region AR1. The row-direction end of the layer 16D is located closer to the memory region AR1 than the row-direction end of the layer 16C is. The layers 16C and 16D extend in the row direction by having a width WLMa, bend at a certain position to the column direction by having the width WLMa, and then bend to the row direction by having a width WLMAb larger than the width WLMa. The width WLMa of the layers 16C and 16D is the minimum transfer size of the lithography technologies.

Thereafter, the same manufacturing steps as in the first embodiment are carried out. That is, as shown in FIG. 7B, after the second mask layer 16 is slimmed, a first side wall film 21 is formed on the side walls of the second mask layer 16. The first side wall film 21 is formed continuously on the side walls of the second mask layer 16 to form a closed loop structure. The width WLM1-L of the first side wall film 21 is approximately twice as large as the width of the interconnection portions WLa. In a region where the first side wall film 21 is arranged at regular intervals, the distance WLM1-S between the first side wall film 21 at one position and the first side wall film 21 at an adjoining position is substantially equal to the width WLM1-L of the first side wall film 21.

As shown in FIG. 7C, wet etching is carried out to remove the second mask layer 16 but to leave the first side wall film 21 based on an etching selectivity between the second mask layer 16 and the first side wall film 21. Then, resists 22 are formed to cover some portions of the first side wall film 21. The resists 22 have a rectangular shape extending in the row direction, and are arranged to adjoin each other in the column direction. The resists 22 are formed about the regions where the connection portions WLb are to be formed later. At this time, it is preferable to arrange the resists 22 with the same size and in a certain pattern. That is, it is preferable to arrange the row-direction ends of the resists 22 on straight lines extending in the column direction. The width WLML-L of the resists 22 is formed larger than the width WLM1-L and distance WLM1-S of the first side wall film 21. The resists 22 will be used later for forming the regions P2 of the interconnection portions WLa. The distances WLML-S1 and WLML-S2 between the resists 22 adjoining in the column direction are formed larger than the width WLM1-L and distance WLM1-S of the first side wall film 21.

As shown in FIG. 7D, dry etching is carried out by using the first side wall film 21 and the resists 22 as masks. As a result, such portions of the first mask layer 15 as are not covered by the first side wall film 21 and the resists 22 are removed, and hence the first mask layer 15 is processed into a loop shape. The width WLML-L of such portions of the first mask layer 15 as correspond to where the resists 22 were formed is formed larger than the width WLM1-L of the other portions of the first mask layer 15.

As shown in FIG. 7E, a second side wall film 23 is formed on the side walls of the first mask layer 15. The second side wall film 23 is formed continuously on the side walls of the first mask layer 15 to form a closed loop structure. The width WLM2-L of the second side wall film 23 is substantially equal to the width of the interconnection portions WLa. In a region where the second side wall film 23 is arranged at regular intervals, the distance WLM2-S between the second side wall film 23 at one position and the second side wall film 23 at an adjoining position is substantially equal to the width WLM2-L of the second side wall film 23. The regions P2 of the interconnection portions WLa will be formed where an end portion of the first side wall film 21 and the resists 22 were formed contacting each other (See FIG. 7C).

As shown in FIG. 7F, wet etching is carried out to remove the first mask layer 15 but to leave the second side wall film 23 based on an etching selectivity between the first mask layer 15 and the second side wall film 23. Then, resists 24 are formed to cover some portions of the second side wall film 23. The resists 24 have a rectangular shape extending in the row direction, and are formed about the regions where the connection portions WLb are to be formed later. At this time, in order to provide the resists 24 with a stable shape, it is preferable to arrange the resists 24 at regular intervals with the same size. That is, it is preferable to arrange the resists 24 in line in the column direction. The width WLML2-L of the resists 24 is formed substantially equal to the width of the connection portions WLb and larger than the width WLM2-L and distance WLM2-S of the second side wall film 23. The distance WLML2-S between such resists 24 as were located on both sides of the first mask layer 15, which was removed, and as are adjoining each other in the column direction is formed larger than the width WLM2-L and distance WLM2-S of the second side wall film 23.

As shown in FIG. 7G, dry etching is carried out by using the second side wall film 23 and the resists 24 as masks. As a result, such portions of the protecting layer 14 as are not covered by the second side wall film 23 and the resists 24 and such portions of the conducting layer 13 as are located under these portions are removed so that the protecting layer 14 and the conducting layer 13 are processed into a loop shape. After this processing, the protecting layer 14 is removed.

As shown in FIG. 7H, a resist 25 for covering the conducting layer 13 is formed. The resist 25 has linear windows 25A1 and 25A2 extending in the column direction. After this, etching is carried out to such portions of the conducting layer 13 as are exposed through the windows 25A1 and 25A2 to process the conducting layer 13 so as to destroy its loop structure. The resist 25 having the linear windows 25A1 and 25A2 enables minute processing, and allows the connection portions WLb to be formed with precision. Through the steps shown in FIG. 7A to FIG. 7H, the conducting layer 13 is processed into the shapes of the word lines WL according to the fourth embodiment. As a result, the ends of the connection portions WLb become parallel with straight lines extending in the column direction.

By using a double side-wall process like in the first embodiment, it is possible to manufacture a miniaturized nonvolatile semiconductor memory device.

### Fifth Embodiment

### Configuration

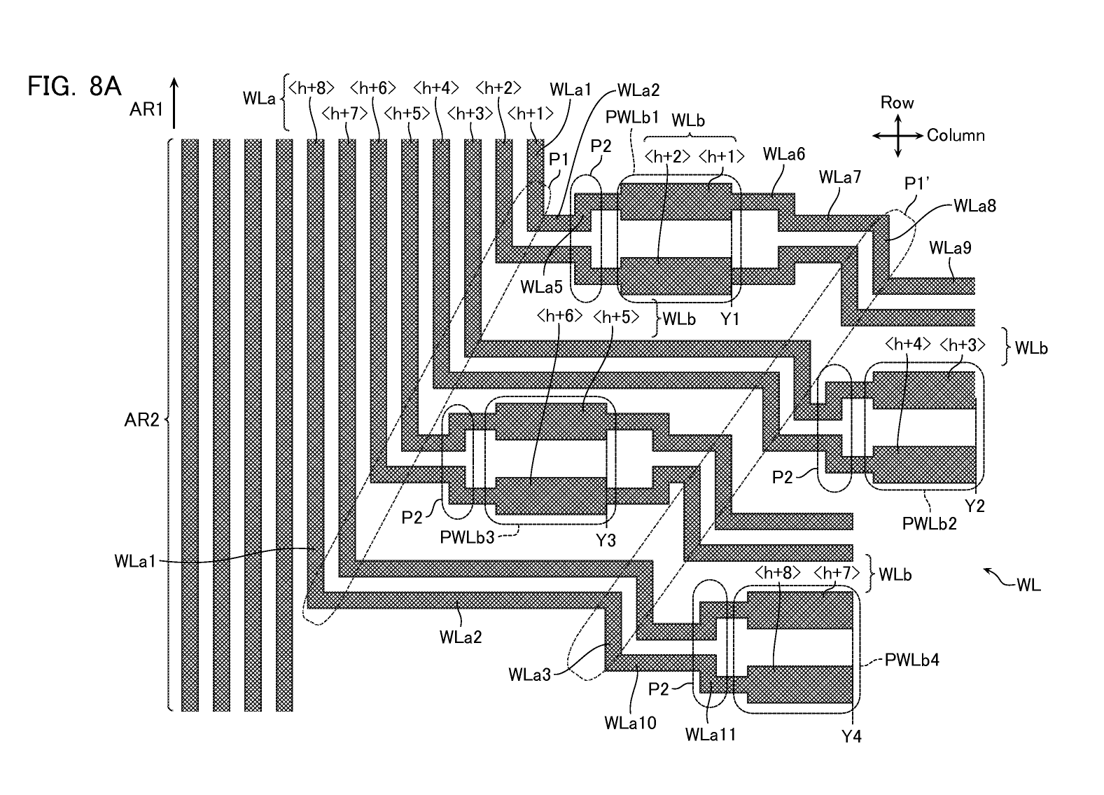

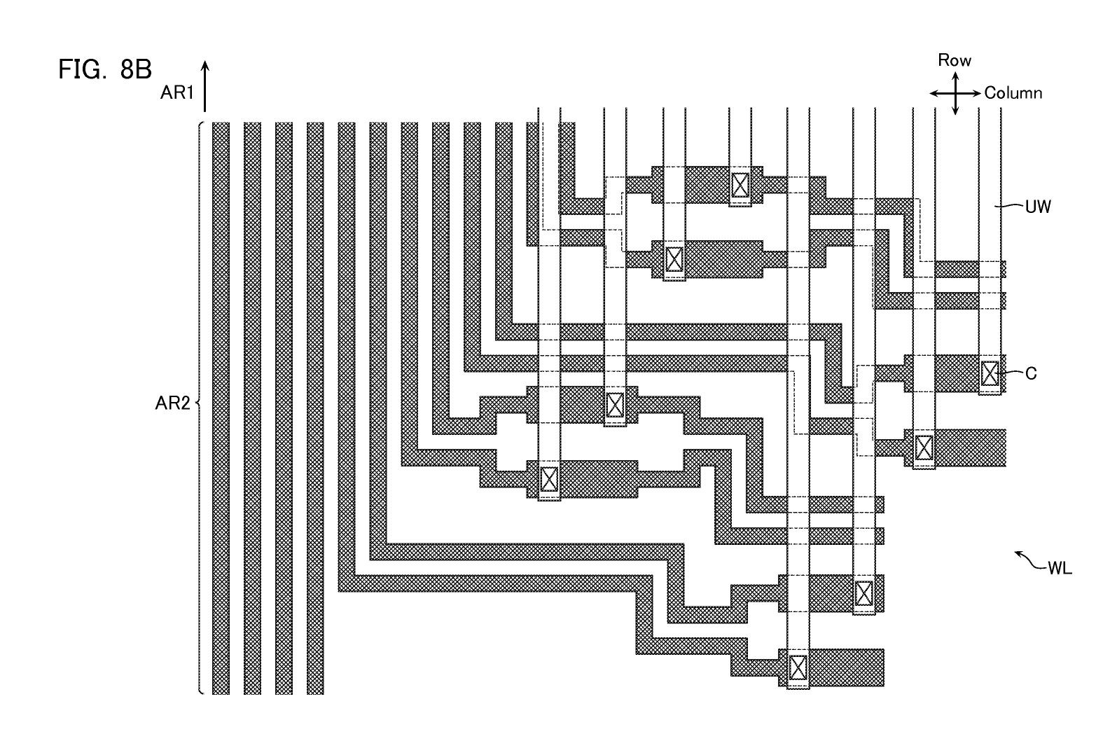

Next, the configuration of a nonvolatile semiconductor memory device according to a fifth embodiment will be explained with reference to FIGS. 8A, 8B. Any components of the fifth embodiment that are the same as the first to fourth embodiments will be denoted by the same reference numerals and will not be explained again. FIG. 8A only shows interconnection portions WLa<h+1> to WLa<h+8> and connection portions WLb<h+1> to WLb<h+8> in a simplified manner. FIG. 8B shows word lines WL, and upper interconnection lines UW.

The fifth embodiment is different from the first to fourth embodiments in the arrangement of the connection portions WLb. In the fifth embodiment, a two's power number of (for example, 64) connection portions WLb for one memory unit MU are not arranged oppositely to each other in the row direction.

In the fifth embodiment, a plurality of connection portions WLb<h+1> to WLb<h+8> include connection portion pairs PWLb1 to PWLb4, which are configured by pairing the connection portions WLb<h+1> to WLb<h+8>. The connection portion pair PWLb1 is configured by the connection portions WLb<h+1> and WLb<h+2> connected to adjoining interconnection portions WLa<h+1> and WLa<h+2>. The connection portion pair PWLb2 is configured by the connection portions WLb<h+3> and WLb<h+4> connected to adjoining interconnection portions WLa<h+3> and WLa<h+4>. The connection portion pair PWLb3 is configured by the connection portions WLb<h+5> and WLb<h+6> connected to adjoining interconnection portions WLa<h+5> and WLa<h+6>. The connection portion pair PWLb4 is configured by the connection portions WLb<h+7> and WLb<h+8> connected to adjoining interconnection portions WLa<h+7> and WLa<h+8>.

Each of the connection portion pairs PWLb1 to PWLb4 is arranged such that the ends of its connection portions WLb are along a straight line extending in the row direction. The connection portion pairs PWLb1 to PWLb4 have their ends located at different positions in the column direction. Specifically, the end of the connection portion pair PWLb1 is positioned in parallel with a straight line Y1 extending in the row direction. The end of the connection portion pair PWLb2 is positioned in parallel with a straight line Y2 extending in the row direction. The end of the connection portion pair PWLb3 is positioned in parallel with a straight line Y3 extending in the row direction. The end of the connection portion pair PWLb4 is positioned in parallel with a straight line Y4 extending in the row direction. That is, the column-direction center positions of the connection portion pairs PWLb1 to PWLb4 are different in the column direction. The connection portions WLb are formed in a rectangular shape extending in the column direction. Like in the embodiments described above, unillustrated connection portions WLb may have the same positional relationship as that of the connection portions WLb<h+1> to WLb<h+8> or may be positioned according to another regularity.

In the fifth embodiment, the interconnection portions WLa<h+1>, WLa<h+2>, WLa<h+5>, and WLa<h+6> have a first base portion WLa1 and a second base portion WLa2 as in the first embodiment. Meanwhile, the interconnection portions WLa<h+1>, WLa<h+2>, WLa<h+5>, and WLa<h+6> have fifth to ninth base portions WLa5 to WLa9 instead of the third base portion WLa3 and the fourth base portion WLa4 of the first embodiment. The fifth base portion WLa5 is formed in an L shape extending in the row direction and the column direction. The end of such a portion of the fifth base portion WLa5 as extending in the row direction is connected to the other end of the second base portion WLa2. The end of such a portion of the fifth base portion WLa5 as extending in the column direction is connected to one end of the connection portion WLb. The sixth base portion WLa6 is formed in an L shape extending in the row direction and the column direction. The end of such a portion of the sixth base portion WLa6 as extending in the column direction is connected to the other end of the connection portion WLb. The seventh base portion WLa7 has its one end connected to the end of such a portion of the sixth base portion WLa6 as extending in the row direction and extends in the column direction. The eighth base portion WLa8 has its one end connected to the other end of the seventh base portion WLa7 and extends in the row direction. The ninth base portion WLa9 has its one end connected to the other end of the eighth base portion WLa8 and extends in the column direction. The other end of the ninth base portions WLa9 of the interconnection portions WLa<h+1> and WLa<h+2> is in parallel with the straight line Y2. The other end of the ninth base portions WLa9 of the interconnection portions WLa<h+5> and WLa<h+6> is in parallel with the straight line Y4.

In the fifth embodiment, the interconnection portions WLa<h+3>, WLa<h+4>, WLa<h+7>, and WLa<h+8> have first to third base portions WLa1 to WLa3 as in the first embodiment. Meanwhile, the interconnection portions WLa<h+3>, WLa<h+4>, WLa<h+7>, and WLa<h+8> have a tenth base portion WLa10 and an eleventh base portion WLa11 instead of the fourth base portion WLa4 of the first embodiment. The tenth base portion WLa10 has its one end connected to the other end of the third base portion WLa3 and extends in the column direction. The eleventh base portion WLa11 is formed in an L shape extending in the row direction and the column direction. The end of such a portion of the eleventh base portion WLa11 as extending in the row direction is connected to the other end of the tenth base portion WLa10. The end of such a portion of the eleventh base portion WLa11 as extending in the column direction is connected to one end of the connection portion WLb.

The fifth embodiment can save the occupation area of the word lines WL like the first embodiment, based on the connection portions WLb arranged in the simple pattern described above. The word lines WL are miniaturized by a double side-wall process to be described later. That is, the fifth embodiment can save the occupation area of the nonvolatile semiconductor memory device.

Specifically, the connection portions WLb are positioned in a large space in the column direction side of the region P1, by being positioned after the interconnection portions WLa have been bent to the column direction. The fifth embodiment is particularly effective when there are many word lines WL and a large space is generated in the column direction side of the region P1. As a result, it is possible to shorten the length of the word lines WL in the row direction. For example, the fifth embodiment can reduce the occupation area of the word lines WL to approximately 65% or lower as compared with FIG. 4A, FIG. 10, and FIG. 11 of Patent Document 1. That is, like the first embodiment, the fifth embodiment can save the occupation area of the nonvolatile semiconductor memory device.

Moreover, it is possible to secure a larger positioning space for each of the connection portions WLb than in the first to fourth embodiments, by bending the interconnection portions WLa to the column direction plural times. Therefore, the fifth embodiment can suppress defects and short-circuits of the connection portions WLb and improve the yield ratio.

Further, it is possible to make the distance between the connection portions WLb larger than the distance between the interconnection portions WLa, by utilizing the large space beyond the region P1 shown in FIG. 8A. Likewise, it is possible to make the width of the connection portions WLb larger than the width of the interconnection portions WLa. As a result, it is possible to provide contacts C at the connection portions WLb securely.

In the fifth embodiment, the connection portion pairs PWLb1 to PWLb4 extend in the column direction. As a result, it is possible to position the contacts C for the connection portions WLb of the respective connection portion pairs PWLb1 to PWLb4 at different positions in the column direction. Further, the column-direction center positions of the connection portion pairs PWLb1 to PWLb4 are different in the column direction. As a result, it is possible to position the contacts C for the connection portions WLb of the respective connection portion pairs PWLb1 to PWLb4 at different positions in the column direction in FIG. 8B. These effects can contribute to facilitating wiring of upper interconnection lines (corresponding to the upper interconnection lines UW of the third embodiment). Furthermore, any defects and short-circuits of the upper interconnection lines UW can be suppressed.

Such a layout can be manufactured by a conventional lithography technology. However, applying a double side-wall process to be described later enables to manufacture a miniaturized nonvolatile semiconductor memory device.

[Manufacturing Method]

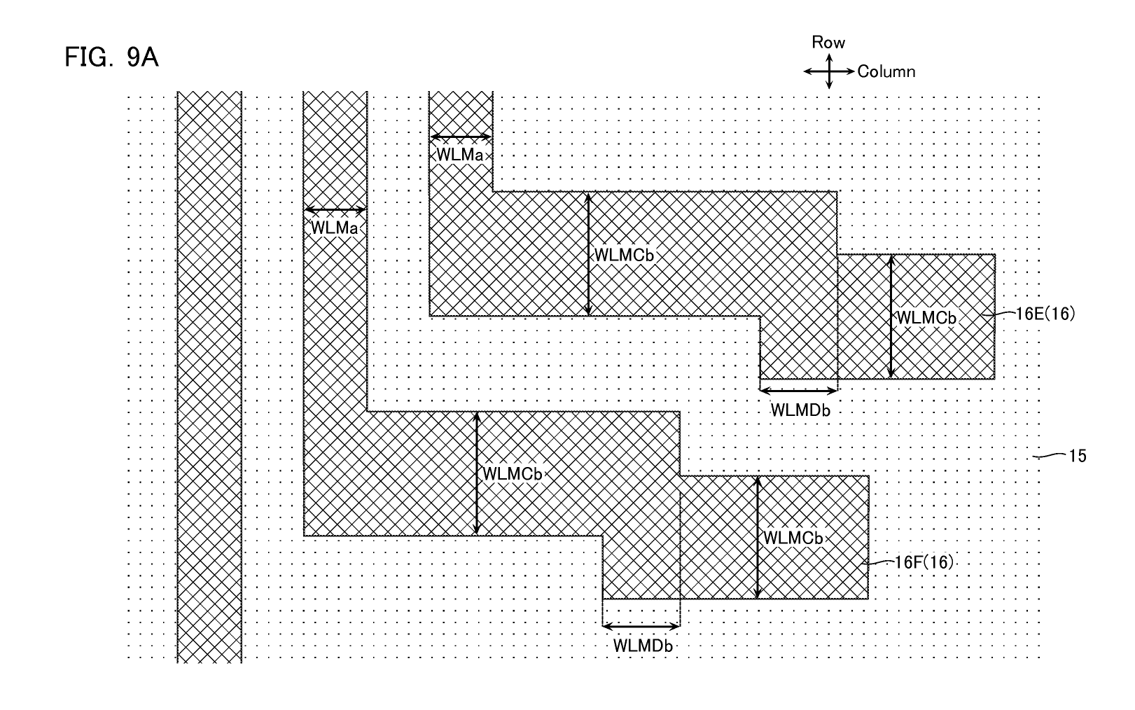

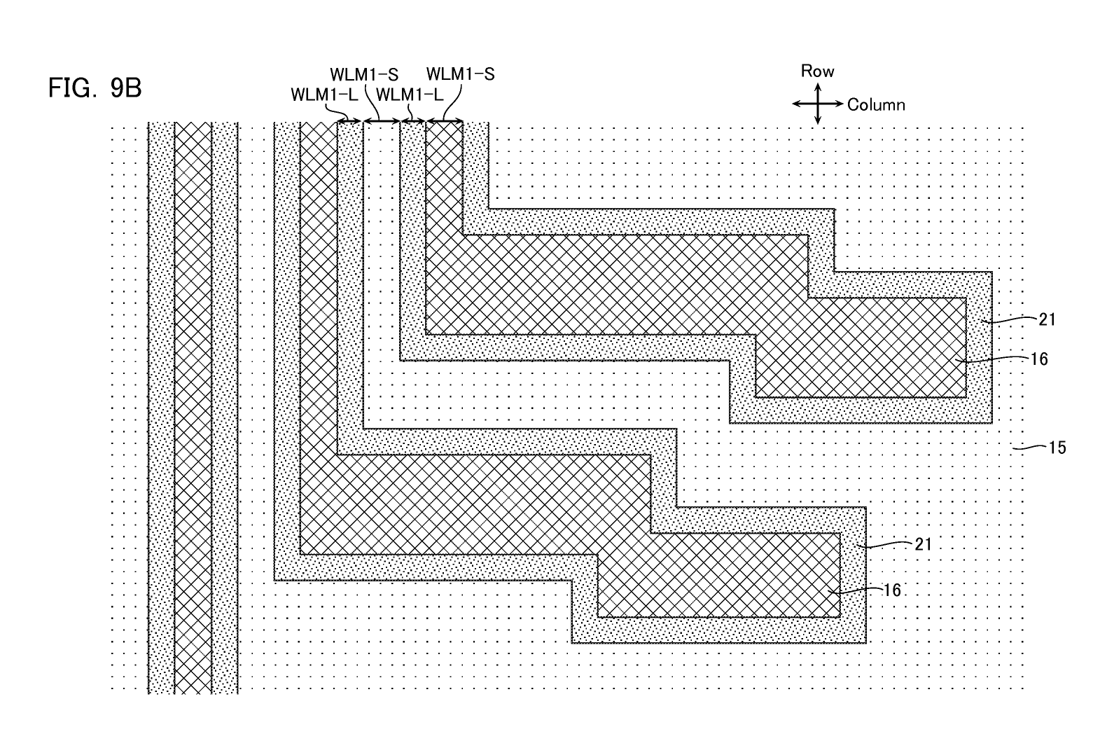

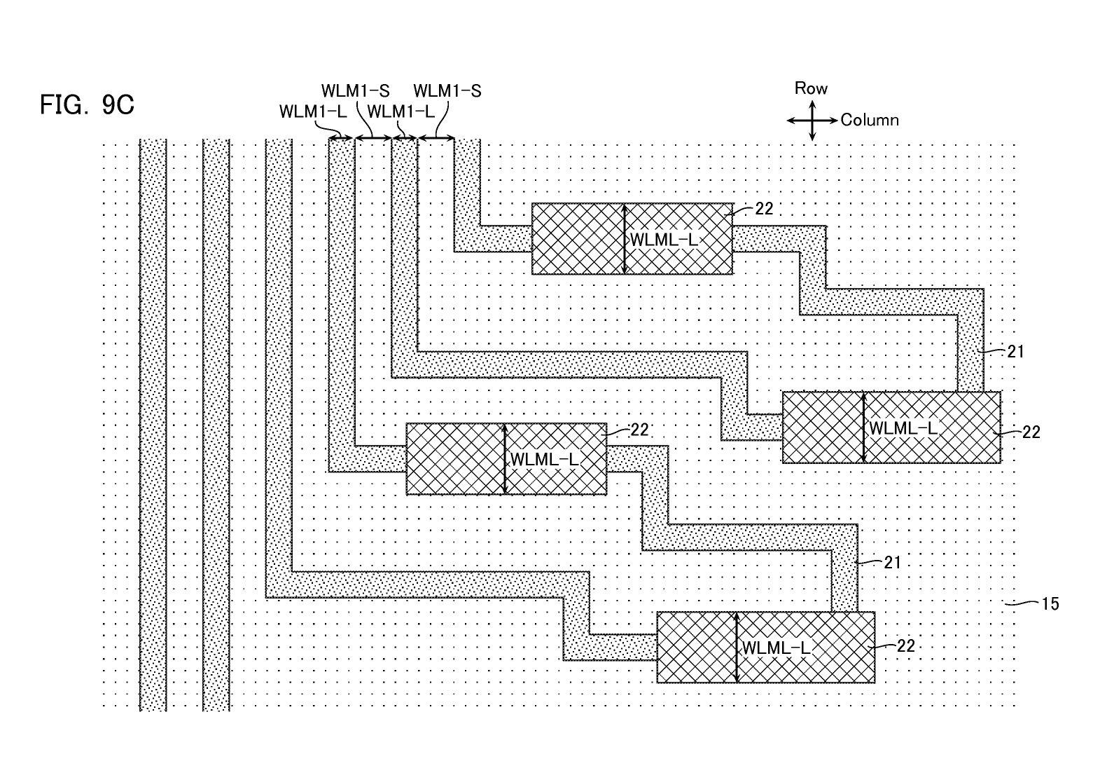

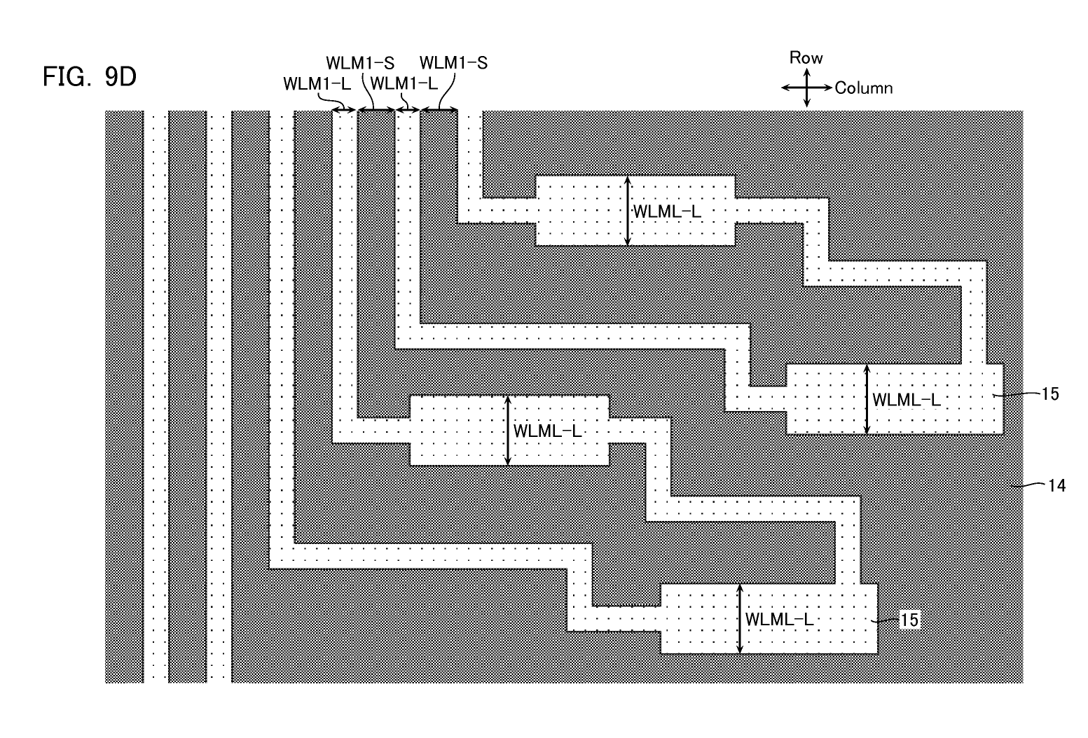

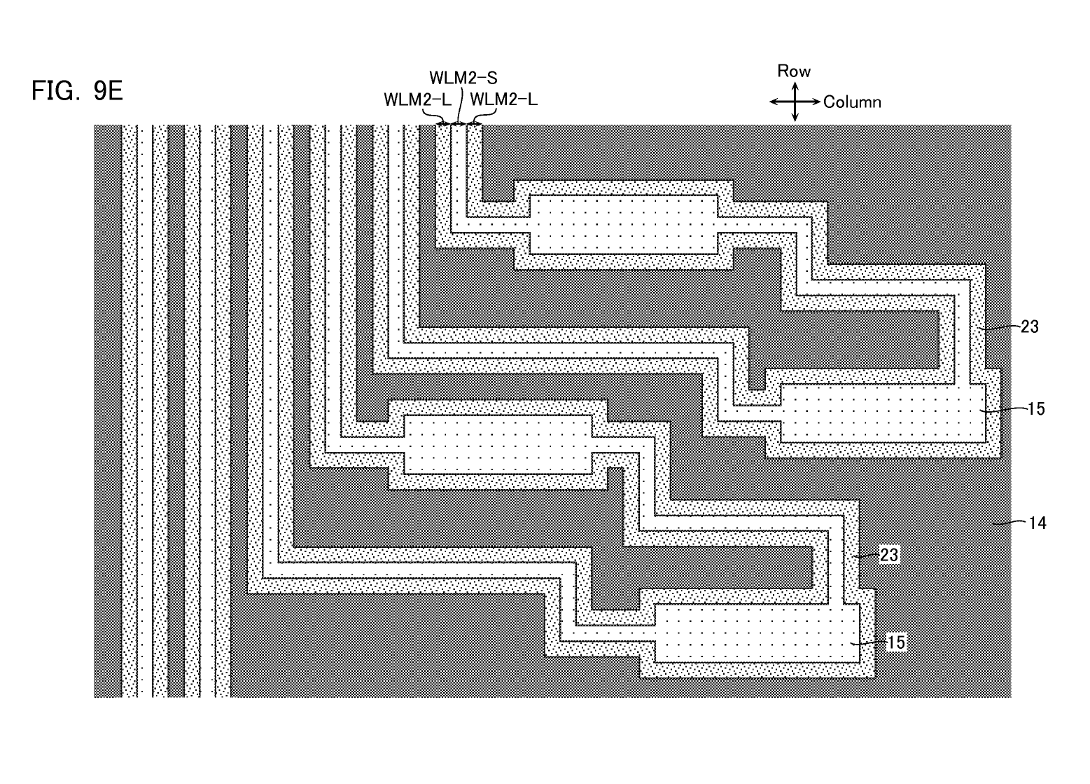

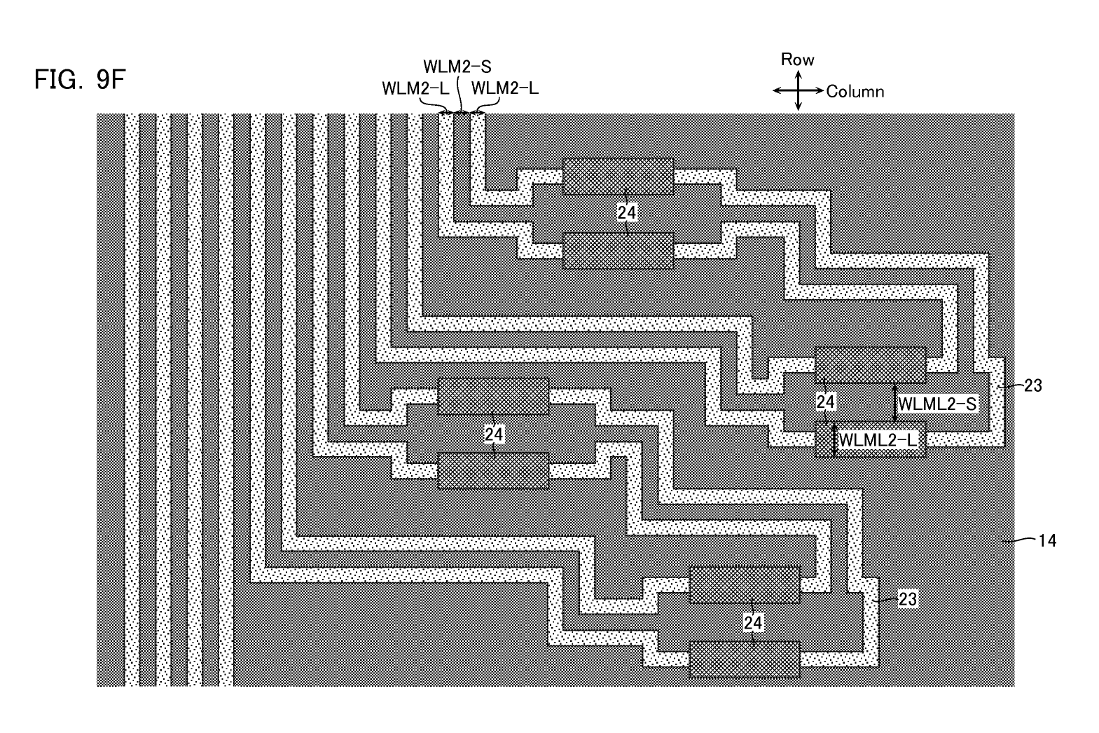

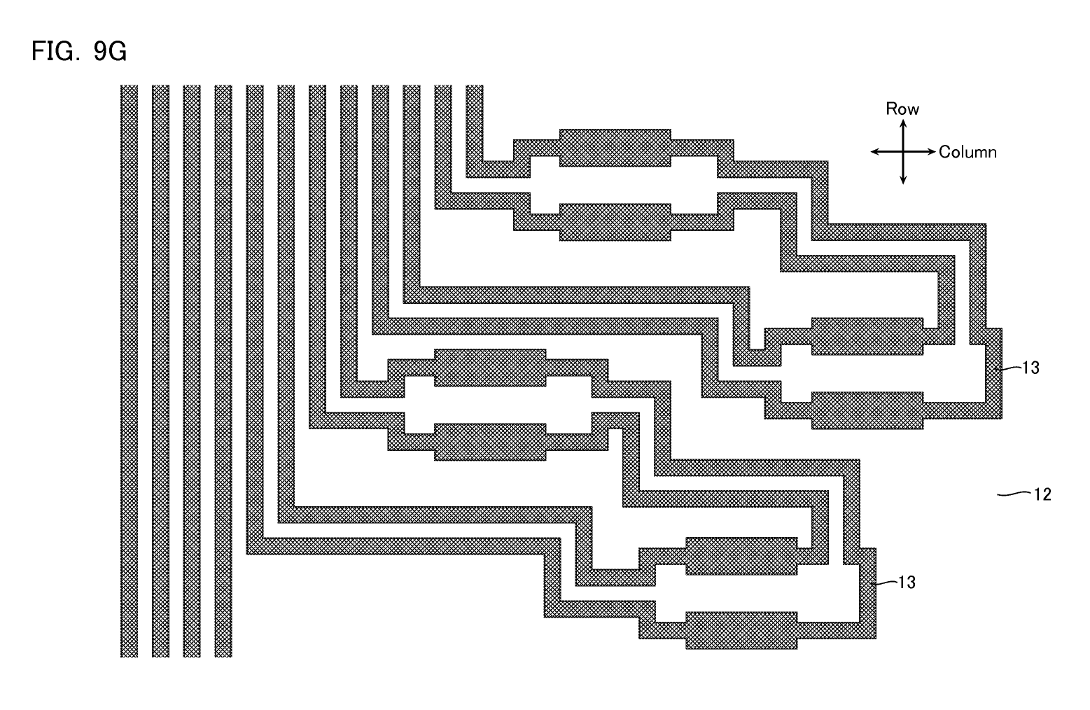

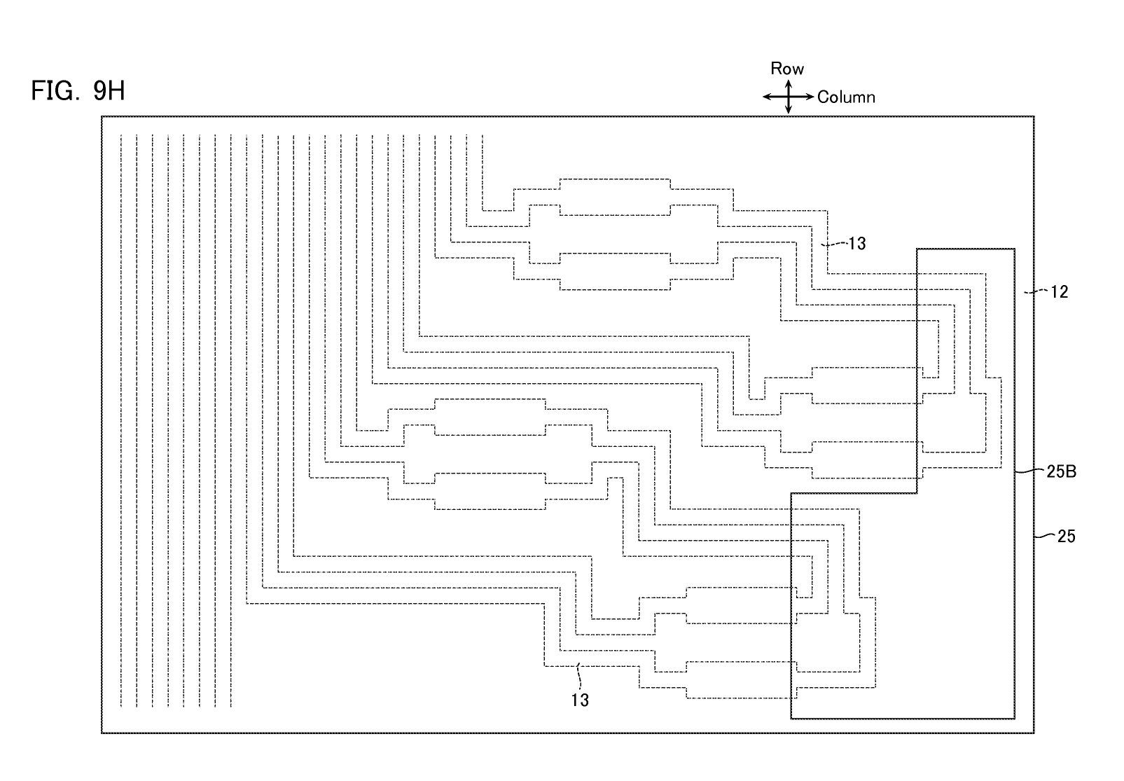

Next, a method of manufacturing the nonvolatile semiconductor memory device according to the fifth embodiment will be explained with reference to FIG. 9A to FIG. 9H. FIG. 9A to FIG. 9H are top views observed in the manufacturing process.

As shown in FIG. 9A, a second mask layer 16 is formed above a first mask layer 15 in a different pattern from that of the first and fourth embodiments. Specifically, the second mask layer 16 includes a layer 16E extending in the column direction, and a layer 16F extending in the same direction as the layer 16E with a certain pitch from the layer 16E in the row direction. The column-direction end of the layer 16E is located at a different position from the column-direction end of the layer 16F. The layers 16E and 16F extend in the row direction by having a width WLMa and bend at a certain position to the column direction by having a width WLMCb larger than the width WLMa. Then, the layers 16E and 16F bend to the row direction by having a width WLMDb larger than the width WLMa, and further bend to the column direction by having the width WLMCb. The width WLMa of the layers 16E and 16F is the minimum resolution limit of the lithography technologies.

Hereinafter, the same manufacturing steps as in the first embodiment are carried out. That is, as shown in FIG. 9B, after the mask layer 16 is slimmed, a first side wall film 21 is formed on the side walls of the second mask layer 16. Here, the first side wall film 21 is formed continuously on the side walls of the second mask layer 16 to form a closed loop structure. The width WLM1-L of the first side wall film 21 is approximately twice as large as the width of the interconnection portions WLa. In a region where the first side wall film 21 is arranged at regular intervals, the distance WLM1-S between the first side wall film 21 at one position and the first side wall film 21 at an adjoining position is substantially equal to the width WLM1-L of the first side wall film 21.

As shown in FIG. 9C, wet etching is carried out to remove the second mask layer 16 but to leave the first side wall film 21 based on an etching selectivity between the second mask layer 16 and the first side wall film 21. Then, resists 22 are formed to cover some portions of the first side wall film 21. The resists 22 have a rectangular shape extending in the column direction, and the column-direction ends of the resists 22 are formed along different straight lines extending in the row direction. The resists 22 are formed about the regions where the connection portions WLb are to be formed later. The width WLML-L of the resists 22 is formed larger than the width WLM1-L and distance WLM1-S of the first side wall film 21. The resists are to be used when forming the regions P2 of the interconnection portions WLa later.

As shown in FIG. 9D, dry etching is carried out by using the first side wall film 21 and the resists 22 as masks. As a result, such portions of the first mask layer 15 as are not covered by the first side wall film 21 and the resists 22 are removed, and hence the first mask layer 15 is processed into a loop shape. The width WLML-L of such portions of the first mask layer 15 as correspond to where the resists 22 were formed is formed larger than the width WLM1-L of the other portions of the first mask layer 15.

As shown in FIG. 9E, a second side wall film 23 is formed on the side walls of the first mask layer 15. The second side wall film 23 is formed continuously on the side walls of the first mask layer 15 to have a closed loop structure. The width WLM2-L of the second side wall film 23 is substantially equal to the width of the interconnection portions WLa. In a region where the second side wall film 23 is arranged at regular intervals, the distance WLM2-S between the second side wall film 23 at one position and the second side wall film 23 at an adjoining position is substantially equal to the width WLM2-L of the second side wall film 23. The regions P2 of the interconnection portions WLa are to be formed where an end of the first side wall film 21 and the resists 22 were formed contacting each other (See FIG. 9C).

As shown in FIG. 9F, wet etching is carried out to remove the first mask layer 15 but to leave the second side wall film 23 based on an etching selectivity between the first mask layer 15 and the second side wall film 23. Then, resists 24 are formed to cover some portions of the second side wall film 23. The resists 24 are formed where the connection portions WLb are to be formed later, and formed with a larger width than that of the second side wall film 23. The resists 24 have a rectangular shape extending in the column direction, and are formed about the regions where the connection portions WLb are to be formed later. The width WLML2-L of the resists 24 is substantially equal to the width of the connection portions WLb, and larger than the width WLM2-L and distance WLM2-S of the second side wall film 23. The distance WLML2-S between such resists 24 as are located on both sides of the first mask layer 15, which was removed, and as are adjoining each other in the row direction is larger than the width WLM2-L and distance WLM2-S of the second side wall film 23.

As shown in FIG. 9G, dry etching is carried out by using the second side wall film 23 and the resists 24 as masks. As a result, such portions of the protecting layer 14 as are not covered by the second side wall film 23 and the resists 24 and such portions of the conducting layer 13 as are located under these portions are removed, and hence the protecting layer 14 and the conducting layer 13 are processed into a loop shape. After this processing, the protecting layer 14 is removed.

As shown in FIG. 9H, a resist 25 for covering the conducting layer 13 is formed. The resist 25 has an L-shaped window 25B. After this, etching is carried out to such portions of the conducting layer 13 as are exposed through the window 25B to process the conducting layer 13 so as to destroy its loop structure. As can be understood, since no conducting layer 13 is formed at one edge, a margin allowed for aligning the resist 25 having the L-shaped window 25B is large. This enables minute processing and allows the connection portions WLb to be formed with precision. Through the steps shown in FIG. 9A to FIG. 9H, the conducting layer 13 is processed into the shape of the word lines WL according to the fifth embodiment. As a result, the ends of the connection portion pairs PWLb1 to PWLb4 become parallel with straight lines extending in the row direction.

By applying a double side-wall process like as applied to the transistors of the first embodiment, it is possible to manufacture a miniaturized nonvolatile semiconductor memory device.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a first region including a plurality of electrically-rewritable memory transistors;
a second region located around the first region; and
a plurality of word lines connected to gates of the plurality of memory transistors respectively,
the plurality of word lines respectively including:
interconnection portions extending in a first direction to head from the first region to the second region, the interconnection portions being arrayed in a second direction orthogonal to the first direction with a first distance therebetween; and
connection portions extending from the interconnection portions, located in the second region, and electrically connected to contacts, respectively,
ends of the connection portions being formed along straight lines extending in the second direction.

2. The nonvolatile semiconductor memory device according to claim 1,
wherein each of the interconnection portions includes:
a first base portion extending in the first direction across the first region and the second region, and having one end in the second region;
a second base portion extending in the second direction with one end thereof contacting the one end of the first base portion; and
a third base portion extending in the first direction with one end thereof contacting the other end of the second base portion,
the connection portions are arranged at the other end side of the third base portions with a distance larger than the first distance provided therebetween in the second direction, and
a width of the connection portions is larger than a width of the interconnection portions.

3. The nonvolatile semiconductor memory device according to claim 1,
wherein the connection portions are arranged oppositely to each other in the first direction.

4. The nonvolatile semiconductor memory device according to claim 3,
wherein the connection portions are arranged in a staggered formation.

5. The nonvolatile semiconductor memory device according to claim 1,
wherein each of the interconnection portions includes:
a first base portion extending in the first direction across the first region and the second region, and having one end in the second region;
a second base portion extending in the second direction with one end thereof contacting the one end of the first base portion; and
a third base portion extending in the first direction with one end thereof contacting the other end of the second base portion,
the connection portion are arranged at the other end side of the third base portions with a distance larger than the first distance provided therebetween in the second direction,
the plurality of word lines further include at least one pair of connection portion groups each made by plural ones of the connection portions,
ends of the connection portions included in one of the connection portion groups and ends of the connection portions included in the other of the connection portion groups are formed along different straight lines extending in the second direction, and
the at least one pair of connection portion groups are located on straight lines extending in the second direction.

6. The nonvolatile semiconductor memory device according to claim 5,
wherein a width of the connection portions is larger than a width of the interconnection portions.

7. The nonvolatile semiconductor memory device according to claim 1,
wherein the interconnection portions are bent by 90 degrees at a first position in the second region, and
a length from a boundary between the first region and the second region to the first position is larger than a quadruple of a width of the interconnection portions.

8. A nonvolatile semiconductor memory device, comprising:
a first region including a plurality of electrically-rewritable memory transistors;
a second region located around the first region; and
a plurality of word lines connected to gates of the plurality of memory transistors respectively,
the plurality of word lines respectively including:
interconnection portions extending in a first direction to head from the first region to the second region, the interconnection portions being arrayed in a second direction orthogonal to the first direction with a first distance therebetween; and
connection portions extending from the interconnection portions, located in the second region, and electrically connected to contacts, respectively,
the connection portions include a plurality of connection portion pairs each of which is a pair of connection portions,
each of the plurality of connection portion pairs is formed such that ends of the connection portions are along a straight line extending in the first direction, and
the plurality of connection portion pairs have the ends located at different positions in the second direction.

9. The nonvolatile semiconductor memory device according to claim 8,
wherein a width of the connection portions is larger than a width of the interconnection portions.

10. A method of manufacturing a nonvolatile semiconductor memory device, comprising:
forming a first mask above a conducting layer;
forming a second mask having a first pattern above the first mask;
forming a first side wall film on side walls of the second mask;
removing the second mask while leaving the first side wall film;
forming a third mask having a larger width than that of the first side wall film above the first side wall film;
removing such portions of the first mask as are not covered by the first side wall film and the third mask to process the first mask into a loop shape;
removing the first side wall film and the third mask;
forming a second side wall film on side walls of the first mask, and removing the first mask while leaving the second side wall film;
forming a fourth mask having a larger width than that of the second side wall film above the second side wall film;
removing such portions of the conducting layer as are not covered by the second side wall film and the fourth mask to process the conducting layer into a loop shape; and
removing the conducting layer partially to process the conducting layer such that the loop shape is destroyed.

11. The method of manufacturing a nonvolatile semiconductor memory device according to claim 10,
wherein the second mask is formed to have a loop shape when seen from above.

12. The method of manufacturing a nonvolatile semiconductor memory device according to claim 10, comprising
forming the first side wall film on the side walls of the second mask after slimming the second mask.

13. The method of manufacturing a nonvolatile semiconductor memory device according to claim 10, comprising
carrying out wet etching to the second mask and the first side wall film to remove the second mask based on an etching selectivity between the second mask and the first side wall film.

14. The method of manufacturing a nonvolatile semiconductor memory device according to claim 10, comprising
carrying out wet etching to the first mask and the second side wall film to remove the first mask based on an etching selectivity between the first mask and the second side wall film.

15. The method of manufacturing a nonvolatile semiconductor memory device according to claim 10, comprising
forming a plurality of the third masks,
wherein the plurality of third masks are formed in a same shape and arranged at regular intervals.

16. The method of manufacturing a nonvolatile semiconductor memory device according to claim 10, comprising
forming a plurality of the fourth masks,
wherein the plurality of fourth masks are formed in a same shape and arranged at regular intervals.

17. The method of manufacturing a nonvolatile semiconductor memory device according to claim 10, comprising
forming a fifth mask above the conducting layer and carrying out etching to the conducting layer through the fifth mask to process the conducting layer such that the loop shape is destroyed,
wherein the fifth mask has an opening having a linear shape when seen from above.

18. The method of manufacturing a nonvolatile semiconductor memory device according to claim 10, comprising
forming a fifth mask above the conducting layer and carrying out etching to the conducting layer through the fifth mask to process the conducting layer such that the loop shape is destroyed,
wherein the fifth mask has an opening having an L shape when seen from above.
